(19) United States
(12) Patent Application Publication
(10) Pub. No.: US 2023/0038038 A1
(43) Pub. Date: Feb. 9, 2023

(54) LIDAR SYSTEM WITH SEMICONDUCTOR WINDOW

(71) Applicant: Luminar, LLC, Orlando, FL (US)

(72) Inventors: Stephen L. Mielke, Oviedo, FL (US); Stephen D. Gaalema, Colorado Springs, CO (US); Rand Dannenberg, Los Angeles, CA (US); Philip Buchsbaum, Oldsmar, FL (US); James L. Gates, Las Vegas, NV (US)

(21) Appl. No.: 17/881,850

(22) Filed: Aug. 5, 2022

Related U.S. Application Data
(60) Provisional application No. 63/229,684, filed on Aug. 5, 2021.

(51) Int. Cl. G01S 7/481; G01S 17/931; H05K 9/00

(52) U.S. Cl. CPC G01S 7/4813; G01S 17/931; H05K 9/0094

(57) ABSTRACT

A system includes a light source, a receiver, and an enclosure. The light source is configured to emit an optical signal and the receiver is configured to detect a received optical signal including at least a portion of the emitted optical signal scattered by an external target. The enclosure includes a housing and a semiconductor window. The semiconductor window includes a semiconductor material configured to allow at least a portion of the emitted optical signal and the received optical signal to pass through the semiconductor window. The enclosure, including the housing and the semiconductor window, is configured to attenuate radio-frequency (RF) electromagnetic radiation.

### CROSS REFERENCE TO OTHER APPLICATIONS

This application claims priority to U.S. Provisional Patent Application No. 63/229,684 entitled LIDAR SYSTEM WITH SEMICONDUCTOR WINDOW filed Aug. 5, 2021 which is incorporated herein by reference for all purposes.

### BACKGROUND OF THE INVENTION

Light detection and ranging (lidar) is a technology that can be used to measure distances to remote targets. Typically, a lidar system includes a light source and an optical receiver. The light source can include, for example, a laser which emits light having a particular operating wavelength. The operating wavelength of a lidar system may lie, for example, in the infrared, visible, or ultraviolet portions of the electromagnetic spectrum. The light source emits light towards a target which scatters the light, and some of the scattered light is received back at the receiver. The system determines the distance to the target based on one or more characteristics associated with the received light. For example, the lidar system may determine the distance to the target based on the time of flight for a pulse of light emitted by the light source to travel to the target and back to the lidar system.

### BRIEF DESCRIPTION OF THE DRAWINGS

Various embodiments of the invention are disclosed in the following detailed description and the accompanying drawings.

FIG. 1 illustrates an example light detection and ranging (lidar) system.

FIG. 2 illustrates an example scan pattern produced by a lidar system.

FIG. 3 illustrates an example lidar system with an example rotating polygon mirror.

FIG. 4 illustrates an example light-source field of view (FOV_{L}) and receiver field of view (FOV_{R}) for a lidar system.

FIG. 5 illustrates an example unidirectional scan pattern that includes multiple pixels and multiple scan lines.

FIG. 6 illustrates an example receiver that includes a detector coupled to a signal-detection circuit.

FIG. 7 illustrates an example receiver and an example voltage signal corresponding to a received pulse of light.

FIG. 8 illustrates an example lidar system contained within an enclosure.

FIG. 9 illustrates an example window that includes a conductive coating.

FIG. 10 illustrates an example enclosure that includes a housing, a window, and epoxy.

FIG. 11 illustrates an example enclosure that includes a housing, a window, and a gasket.

FIG. 12 illustrates an example window assembly that includes a semiconductor window and an exterior window.

FIGS. 13-14 each illustrate an example window that includes a heating element.

FIG. 15 illustrates an example measurement of radio-frequency (RF) electromagnetic radiation emitted by a lidar system.

FIG. 16 illustrates an example computer system.

### DETAILED DESCRIPTION

The invention can be implemented in numerous ways, including as a process; an apparatus; a system; a composition of matter; a computer program product embodied on a computer readable storage medium; and/or a processor, such as a processor configured to execute instructions stored on and/or provided by a memory coupled to the processor. In this specification, these implementations, or any other form that the invention may take, may be referred to as techniques. In general, the order of the steps of disclosed processes may be altered within the scope of the invention. Unless stated otherwise, a component such as a processor or a memory described as being configured to perform a task may be implemented as a general component that is temporarily configured to perform the task at a given time or a specific component that is manufactured to perform the task. As used herein, the term ‘processor’ refers to one or more devices, circuits, and/or processing cores configured to process data, such as computer program instructions.

A detailed description of one or more embodiments of the invention is provided below along with accompanying figures that illustrate the principles of the invention. The invention is described in connection with such embodiments, but the invention is not limited to any embodiment. The scope of the invention is limited only by the claims and the invention encompasses numerous alternatives, modifications and equivalents. Numerous specific details are set forth in the following description in order to provide a thorough understanding of the invention. These details are provided for the purpose of example and the invention may be practiced according to the claims without some or all of these specific details. For the purpose of clarity, technical material that is known in the technical fields related to the invention has not been described in detail so that the invention is not unnecessarily obscured.

A semiconductor window for a lidar system is disclosed. Using the disclosed embodiments of a semiconductor window, a lidar system can have significantly improved electromagnetic interference (EMI) properties while maintaining good optical transmission properties for transmitting and receiving light beams. Without significantly impacting optical transparency, the semiconductor window integrated with a housing of a lidar system allows the emitted and received optical signals to exit and enter the enclosure of the lidar system while also attenuating electromagnetic radiation. In various embodiments, the semiconductor window is electrically conductive and is coupled to the housing of the lidar system's enclosure. The enclosure, which includes the semiconductor window and corresponding housing, helps to reduce EMI while the semiconductor window allows for optical signals to be emitted and received. In some embodiments, the semiconductor window is paired with a second exterior window that provides protection from the external environment. The exterior window may be subject to build up of optical obstructions such as snow, ice, and/or other obstructions including other forms of frozen water. In some embodiments, the semiconductor window further includes a heating element used to help remove these obstructions from the external-facing surface of the lidar system. For example, using the included heating element, the semiconductor window can heat up a corresponding exterior window to aid in removing snow, ice, frost, hail, sleet, and/or other temperature-sensitive obstructions.

In some embodiments, a system, such as a lidar system, comprises a light source, a receiver, and an enclosure. For example, a lidar system includes a light source and receiver, among other components, included in an enclosure. The light source is configured to emit an optical signal, such as a light beam or light pulse directed to exit the system. The receiver is configured to detect a received optical signal comprising at least a portion of the emitted optical signal scattered by an external target. For example, once the emitted optical signal leaves the enclosure of the lidar system, at least a portion of the emitted optical signal is scattered by an external target and reflected back to the lidar system where it is received by the receiver as the received optical signal. In various embodiments, the enclosure comprises a housing and a semiconductor window. For example, the enclosure of the lidar system includes at least a housing with a semiconductor window associated with an opening of the housing. The light source and the receiver are included in the enclosure. The semiconductor window comprises a semiconductor material configured to allow at least a portion of the emitted optical signal and the received optical signal to pass through the semiconductor window. The enclosure, including the housing and the semiconductor window, is configured to attenuate radio-frequency (RF) electromagnetic radiation. For example, the semiconductor window is electrically conductive and is coupled to the housing. The enclosure, which includes both the housing and semiconductor window, attenuates RF electromagnetic radiation originating from within the enclosure as well RF electromagnetic radiation originating from outside the enclosure while also allowing both the emitted optical signal and the received optical signal to pass through the window. The attenuated RF electromagnetic radiation includes radiation of a frequency in a range from 300 MHz to 6 GHz. In various embodiments, the semiconductor window provides good optical transmission for optical signals travelling in either direction while also providing suppression against electromagnetic interference (EMI).

In various embodiments, the semiconductor window can be affixed to the housing using one or more electrically conductive materials and/or techniques, such as by using a conductive adhesive, a conductive epoxy, a conductive coating, and/or a conductive gasket. The enclosure of the lidar system can also utilize a separate exterior window. The second window can function as a protective element and can be affixed to or cover the semiconductor window. In some embodiments, an airgap exists between the semiconductor window and the exterior window. In some embodiments, the semiconductor window further includes one or more heating elements. For example, using a heating element deposited on the semiconductor window, the temperature of the semiconductor window can be raised to heat up the exterior window. By heating up the exterior window, different forms of frozen water, such as ice, snow, frost, hail, and sleet, which may otherwise interfere with the transmission of optical signals, can be melted and removed from the external-facing surface of the lidar system including from the exterior window.

A lidar system operates in a vehicle and includes multiple “eyes,” each of which has its own field of regard, or an angular range over which the eye scans targets using pulses of light in accordance with a scan pattern. The fields of regard can combine along a certain dimension (e.g., horizontally) to define the overall field of regard of the lidar system. The lidar system then can use data received via both eyes to generate a point cloud or otherwise process the received data.

In a two-eye configuration of the lidar system, the two eyes can be housed together and scan the respective fields of regard via a shared window or separate windows, or the eyes can be housed separately. In the latter case, an assembly referred to as a “sensor head” can include a scanner, a receiver, and an optical element such as a collimator or a laser diode to generate or convey a beam of light.

Depending on the implementation, each eye of a lidar system can include a separate scanner (e.g., each eye can be equipped with a pivotable scan mirror to scan the field of regard vertically and another pivotable scan mirror to scan the field of regard horizontally), a partially shared scanner (e.g., each eye can be equipped with a pivotable scan mirror to scan the field of regard vertically, and a shared polygon mirror can scan the corresponding fields of regard horizontally, using different reflective surfaces), or a fully shared scanner (e.g., a pivotable planar mirror can scan the fields of regard vertically by reflecting incident beams at different regions on the reflective surface, and a shared polygon mirror can scan the corresponding fields of regard horizontally, using different reflective surfaces).

Different hardware configurations allow the lidar system to operate the eyes more independently of each other, as is the case with separate scanners, or less independently, as is the case with a fully shared scanner. For example, the two or more eyes may scan the respective fields of regard using similar or different scan patterns. In one implementation, the two eyes trace out the same pattern, but with a certain time differential to maintain angular separation between light-source fields of view and thereby reduce the probability of cross-talk events between the sensor heads. In another implementation, the two eyes scan the corresponding fields of regard according to different scan patterns, at least in some operational states (e.g., when the vehicle is turning right or left).

Further, according to one approach, two eyes of a lidar system are arranged so that the fields of regard of the eyes are adjacent and non-overlapping. For example, each field of regard can span approximately 60 degrees horizontally and 30 degrees vertically, so that the combined field of regard of the lidar system spans approximately 120 degrees horizontally and 30 degrees vertically. The corresponding scanners (or paths within a shared scanner) can point away from each other at a certain angle, for example, so that the respective fields of regard abut approximately at an axis corresponding to the forward-facing direction of the vehicle.

Alternatively, the lidar system can operate in a “cross-eyed” configuration to create an area of overlap between the fields of regard. The area of overlap can be approximately centered along the forward-facing direction or another direction, which in some implementations a controller can determine dynamically. In this implementation, the two sensor heads can yield a higher density of scan in the area that generally is more important. In some implementations, the fields of regard in a cross-eyed two-eye configuration are offset from each other by a half-pixel value, so that the area of overlap has twice as many pixels. In general, the fields of regard can overlap angularly or translationally. To reduce the probability of cross-talk events (e.g., the situation when a pulse emitted by the light source associated with the first eye is received by the receiver of the second eye), the lidar system can use output beams with different wavelengths.

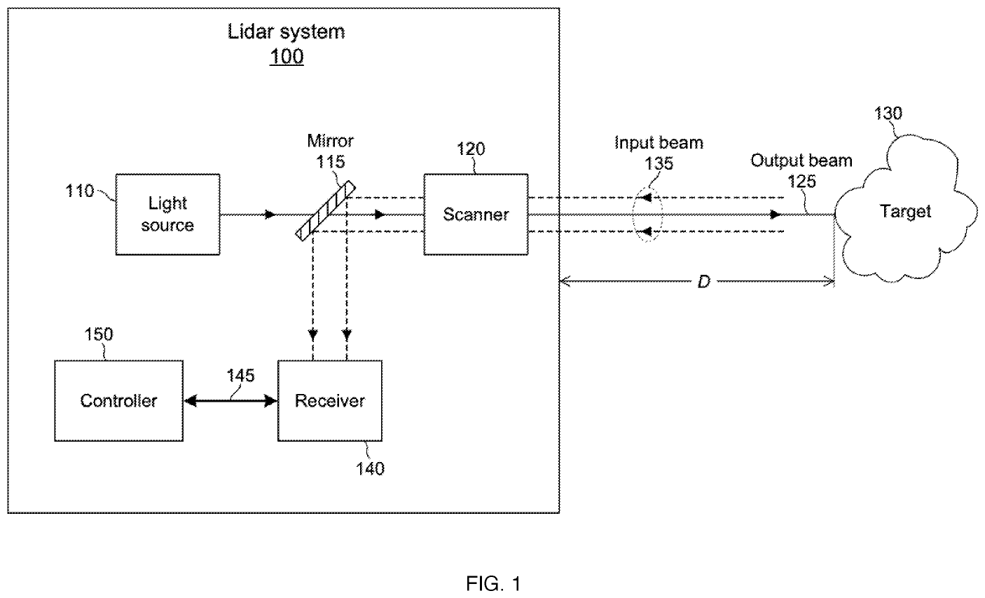

FIG. 1 illustrates an example light detection and ranging (lidar) system 100. In particular embodiments, a lidar system 100 may be referred to as a laser ranging system, a laser radar system, a LIDAR system, a lidar sensor, or a laser detection and ranging (LADAR or ladar) system. In particular embodiments, a lidar system 100 may include a light source 110, mirror 115, scanner 120, receiver 140, or controller 150. The light source 110 may include, for example, a laser which emits light having a particular operating wavelength in the infrared, visible, or ultraviolet portions of the electromagnetic spectrum. As an example, light source 110 may include a laser with one or more operating wavelengths between approximately 900 nanometers (nm) and 2100 nm. The light source 110 emits an output beam of light 125 which may be continuous wave (CW), pulsed, or modulated in any suitable manner for a given application. The output beam of light 125 is directed downrange toward a remote target 130. As an example, the remote target 130 may be located a distance D of approximately 1 m to 1 km from the lidar system 100.

Once the output beam 125 reaches the downrange target 130, the target may scatter or reflect at least a portion of light from the output beam 125, and some of the scattered or reflected light may return toward the lidar system 100. In the example of FIG. 1, the scattered or reflected light is represented by input beam 135, which passes through scanner 120 and is reflected by mirror 115 and directed to receiver 140. In particular embodiments, a relatively small fraction of the light from output beam 125 may return to the lidar system 100 as input beam 135. As an example, the ratio of input beam 135 average power, peak power, or pulse energy to output beam 125 average power, peak power, or pulse energy may be approximately 10⁻¹, 10⁻², 10⁻³, 10⁻⁴, 10⁻⁵, 10⁻⁶, 10⁻⁷, 10⁻⁸, 10⁻⁹, 10⁻¹⁰, 10⁻¹¹, or 10⁻¹². As another example, if a pulse of output beam 125 has a pulse energy of 1 microjoule (μJ), then the pulse energy of a corresponding pulse of input beam 135 may have a pulse energy of approximately 10 nanojoules (nJ), 1 nJ, 100 picojoules (pJ), 10 pJ, 1 pJ, 100 femtojoules (fJ), 10 fJ, 1 fJ, 100 attojoules (aJ), 10 aJ, 1 aJ, or 0.1 aJ.

In particular embodiments, output beam 125 may include or may be referred to as an optical signal, output optical signal, emitted optical signal, output light, emitted pulse of light, laser beam, light beam, optical beam, emitted beam, emitted light, or beam. In particular embodiments, input beam 135 may include or may be referred to as a received optical signal, received pulse of light, input pulse of light, input optical signal, return beam, received beam, return light, received light, input light, scattered light, or reflected light. As used herein, scattered light may refer to light that is scattered or reflected by a target 130. As an example, an input beam 135 may include: light from the output beam 125 that is scattered by target 130; light from the output beam 125 that is reflected by target 130; or a combination of scattered and reflected light from target 130.

In particular embodiments, receiver 140 may receive or detect photons from input beam 135 and produce one or more representative signals. For example, the receiver 140 may produce an output electrical signal 145 that is representative of the input beam 135, and the electrical signal 145 may be sent to controller 150. In particular embodiments, receiver 140 or controller 150 may include a processor, computing system (e.g., an ASIC or FPGA), or other suitable circuitry. A controller 150 may be configured to analyze one or more characteristics of the electrical signal 145 from the receiver 140 to determine one or more characteristics of the target 130, such as its distance downrange from the lidar system 100. This may be done, for example, by analyzing a time of flight or a frequency or phase of a transmitted beam of light 125 or a received beam of light 135. If lidar system 100 measures a time of flight of T (e.g., T represents a round-trip time of flight for an emitted pulse of light to travel from the lidar system 100 to the target 130 and back to the lidar system 100), then the distance D from the target 130 to the lidar system 100 may be expressed as D=c·T/2, where c is the speed of light (approximately 3.0×10⁸ m/s). As an example, if a time of flight is measured to be T=300 ns, then the distance from the target 130 to the lidar system 100 may be determined to be approximately D=45.0 m. As another example, if a time of flight is measured to be T=1.33 μs, then the distance from the target 130 to the lidar system 100 may be determined to be approximately D=199.5 m. In particular embodiments, a distance D from lidar system 100 to a target 130 may be referred to as a distance, depth, or range of target 130. As used herein, the speed of light c refers to the speed of light in any suitable medium, such as for example in air, water, or vacuum. As an example, the speed of light in vacuum is approximately 2.9979×10⁸ m/s, and the speed of light in air (which has a refractive index of approximately 1.0003) is approximately 2.9970×10⁸ m/s.

In particular embodiments, light source 110 may include a pulsed or CW laser. As an example, light source 110 may be a pulsed laser configured to produce or emit pulses of light with a pulse duration or pulse width of approximately 10 picoseconds (ps) to 100 nanoseconds (ns). The pulses may have a pulse duration of approximately 100 ps, 200 ps, 400 ps, 1 ns, 2 ns, 5 ns, 10 ns, 20 ns, 50 ns, 100 ns, or any other suitable pulse duration. As another example, light source 110 may be a pulsed laser that produces pulses with a pulse duration of approximately 1-5 ns. As another example, light source 110 may be a pulsed laser that produces pulses at a pulse repetition frequency of approximately 80 kHz to 10 MHz or a pulse period (e.g., a time between consecutive pulses) of approximately 100 ns to 12.5 μs. In particular embodiments, light source 110 may have a substantially constant pulse repetition frequency, or light source 110 may have a variable or adjustable pulse repetition frequency. As an example, light source 110 may be a pulsed laser that produces pulses at a substantially constant pulse repetition frequency of approximately 640 kHz (e.g., 640,000 pulses per second), corresponding to a pulse period of approximately 1.56 μs. As another example, light source 110 may have a pulse repetition frequency (which may be referred to as a repetition rate) that can be varied from approximately 200 kHz to 3 MHz. As used herein, a pulse of light may be referred to as an optical pulse, a light pulse, or a pulse.

In particular embodiments, light source 110 may include a pulsed or CW laser that produces a free-space output beam 125 having any suitable average optical power. As an example, output beam 125 may have an average power of approximately 1 milliwatt (mW), 10 mW, 100 mW, 1 watt (W), 10 W, or any other suitable average power. In particular embodiments, output beam 125 may include optical pulses with any suitable pulse energy or peak optical power. As an example, output beam 125 may include pulses with a pulse energy of approximately 0.01 μJ, 0.1 μJ, 0.5 μJ, 1 μJ, 2 μJ, 10 μJ, 100 μJ, 1 mJ, or any other suitable pulse energy. As another example, output beam 125 may include pulses with a peak power of approximately 10 W, 100 W, 1 kW, 5 kW, 10 kW, or any other suitable peak power. The peak power (Pₚₑₐₖ) of a pulse of light can be related to the pulse energy (E) by the expression E=Pₚₑₐₖ·Δt, where Δt is the duration of the pulse, and the duration of a pulse may be defined as the full width at half maximum duration of the pulse. For example, an optical pulse with a duration of 1 ns and a pulse energy of 1 μJ has a peak power of approximately 1 kW. The average power (Pₐᵥ) of an output beam 125 can be related to the pulse repetition frequency (PRF) and pulse energy by the expression Pₐᵥ=PRF·E. For example, if the pulse repetition frequency is 500 kHz, then the average power of an output beam 125 with 1-μJ pulses is approximately 0.5 W.

In particular embodiments, light source 110 may include a laser diode, such as for example, a Fabry-Perot laser diode, a quantum well laser, a distributed Bragg reflector (DBR) laser, a distributed feedback (DFB) laser, a vertical-cavity surface-emitting laser (VCSEL), a quantum dot laser diode, a grating-coupled surface-emitting laser (GCSEL), a slab-coupled optical waveguide laser (SCOWL), a single-transverse-mode laser diode, a multi-mode broad area laser diode, a laser-diode bar, a laser-diode stack, or a tapered-stripe laser diode. As an example, light source 110 may include an aluminum-gallium-arsenide (AlGaAs) laser diode, an indium-gallium-arsenide (InGaAs) laser diode, an indium-gallium-arsenide-phosphide (InGaAsP) laser diode, or a laser diode that includes any suitable combination of aluminum (Al), indium (In), gallium (Ga), arsenic (As), phosphorous (P), or any other suitable material. In particular embodiments, light source 110 may include a pulsed or CW laser diode with a peak emission wavelength between 1200 nm and 1600 nm. As an example, light source 110 may include a current-modulated InGaAsP DFB laser diode that produces optical pulses at a wavelength of approximately 1550 nm. As another example, light source 110 may include a laser diode that emits light at a wavelength between 1500 nm and 1510 nm.

In particular embodiments, light source 110 may include a pulsed or CW laser diode followed by one or more optical-amplification stages. For example, a seed laser diode may produce a seed optical signal, and an optical amplifier may amplify the seed optical signal to produce an amplified optical signal that is emitted by the light source 110. In particular embodiments, an optical amplifier may include a fiber-optic amplifier or a semiconductor optical amplifier (SOA). For example, a pulsed laser diode may produce relatively low-power optical seed pulses which are amplified by a fiber-optic amplifier. As another example, a light source 110 may include a fiber-laser module that includes a current-modulated laser diode with an operating wavelength of approximately 1550 nm followed by a single-stage or a multi-stage erbium-doped fiber amplifier (EDFA) or erbium-ytterbium-doped fiber amplifier (EYDFA) that amplifies the seed pulses from the laser diode. As another example, light source 110 may include a continuous-wave (CW) or quasi-CW laser diode followed by an external optical modulator (e.g., an electro-optic amplitude modulator). The optical modulator may modulate the CW light from the laser diode to produce optical pulses which are sent to a fiber-optic amplifier or SOA. As another example, light source 110 may include a pulsed or CW seed laser diode followed by a semiconductor optical amplifier (SOA). The SOA may include an active optical waveguide configured to receive a seed optical signal (e.g., pulses of light or CW light) from the seed laser diode and amplify the seed optical signal as it propagates through the waveguide. For example, the seed laser diode may produce relatively low-power seed optical pulses, and the SOA may amplify each seed optical pulse to produce an emitted pulse of light. The optical gain of the SOA may be provided by pulsed or direct-current (DC) electrical current supplied to the SOA. The SOA may be integrated on the same chip as the seed laser diode, or the SOA may be a separate device with an anti-reflection coating on its input facet or output facet. As another example, light source 110 may include a seed laser diode followed by an SOA, which in turn is followed by a fiber-optic amplifier. For example, the seed laser diode may produce relatively low-power seed optical pulses which are amplified by the SOA, and the fiber-optic amplifier may further amplify each of the optical pulses to produce emitted pulses of light.

In particular embodiments, light source 110 may include a direct-emitter laser diode. A direct-emitter laser diode (which may be referred to as a direct emitter) may include a laser diode which produces light that is not subsequently amplified by an optical amplifier. A light source 110 that includes a direct-emitter laser diode may not include an optical amplifier, and the output light produced by a direct emitter may not be amplified after it is emitted by the laser diode. The light produced by a direct-emitter laser diode (e.g., optical pulses, CW light, or frequency-modulated light) may be emitted directly as a free-space output beam 125 without being amplified. A direct-emitter laser diode may be driven by an electrical power source that supplies current pulses to the laser diode, and each current pulse may result in the emission of an output optical pulse.

In particular embodiments, light source 110 may include a diode-pumped solid-state (DPSS) laser. A DPSS laser (which may be referred to as a solid-state laser) may refer to a laser that includes a solid-state, glass, ceramic, or crystal-based gain medium that is pumped by one or more pump laser diodes. The gain medium may include a host material that is doped with rare-earth ions (e.g., neodymium, erbium, ytterbium, or praseodymium). For example, a gain medium may include a yttrium aluminum garnet (YAG) crystal that is doped with neodymium (Nd) ions, and the gain medium may be referred to as a Nd:YAG crystal. A DPSS laser with a Nd:YAG gain medium may produce light at a wavelength between approximately 1300 nm and approximately 1400 nm, and the Nd:YAG gain medium may be pumped by one or more pump laser diodes with an operating wavelength between approximately 730 nm and approximately 900 nm. A DPSS laser may be a passively Q-switched laser that includes a saturable absorber (e.g., a vanadium-doped crystal that acts as a saturable absorber). Alternatively, a DPSS laser may be an actively Q-switched laser that includes an active Q-switch (e.g., an acousto-optic modulator or an electro-optic modulator). A passively or actively Q-switched DPSS laser may produce output optical pulses that form an output beam 125 of a lidar system 100.

In particular embodiments, an output beam of light 125 emitted by light source 110 may be a collimated optical beam having any suitable beam divergence, such as for example, a full-angle beam divergence of approximately 0.5 to 10 milliradians (mrad). A divergence of output beam 125 may refer to an angular measure of an increase in beam size (e.g., a beam radius or beam diameter) as output beam 125 travels away from light source 110 or lidar system 100. In particular embodiments, output beam 125 may have a substantially circular cross section with a beam divergence characterized by a single divergence value. As an example, an output beam 125 with a circular cross section and a full-angle beam divergence of 2 mrad may have a beam diameter or spot size of approximately 20 cm at a distance of 100 m from lidar system 100. In particular embodiments, output beam 125 may have a substantially elliptical cross section characterized by two divergence values. As an example, output beam 125 may have a fast axis and a slow axis, where the fast-axis divergence is greater than the slow-axis divergence. As another example, output beam 125 may be an elliptical beam with a fast-axis divergence of 4 mrad and a slow-axis divergence of 2 mrad.

In particular embodiments, an output beam of light 125 emitted by light source 110 may be unpolarized or randomly polarized, may have no specific or fixed polarization (e.g., the polarization may vary with time), or may have a particular polarization (e.g., output beam 125 may be linearly polarized, elliptically polarized, or circularly polarized). As an example, light source 110 may produce light with no specific polarization or may produce light that is linearly polarized.

In particular embodiments, lidar system 100 may include one or more optical components configured to reflect, focus, filter, shape, modify, steer, or direct light within the lidar system 100 or light produced or received by the lidar system 100 (e.g., output beam 125 or input beam 135). As an example, lidar system 100 may include one or more lenses, mirrors, filters (e.g., bandpass or interference filters), beam splitters, optical splitters, polarizers, polarizing beam splitters, wave plates (e.g., half-wave or quarter-wave plates), diffractive elements, holographic elements, isolators, couplers, detectors, beam combiners, or collimators. The optical components in a lidar system 100 may be free-space optical components, fiber-coupled optical components, or a combination of free-space and fiber-coupled optical components.

In particular embodiments, lidar system 100 may include a telescope, one or more lenses, or one or more mirrors configured to expand, focus, or collimate the output beam 125 or the input beam 135 to a desired beam diameter or divergence. As an example, the lidar system 100 may include one or more lenses to focus the input beam 135 onto a photodetector of receiver 140. As another example, the lidar system 100 may include one or more flat mirrors or curved mirrors (e.g., concave, convex, or parabolic mirrors) to steer or focus the output beam 125 or the input beam 135. For example, the lidar system 100 may include an off-axis parabolic mirror to focus the input beam 135 onto a photodetector of receiver 140. As illustrated in FIG. 1, the lidar system 100 may include mirror 115 (which may be a metallic or dielectric mirror), and mirror 115 may be configured so that light beam 125 passes through the mirror 115 or passes along an edge or side of the mirror 115 and input beam 135 is reflected toward the receiver 140. As an example, mirror 115 (which may be referred to as an overlap mirror, superposition mirror, or beam-combiner mirror) may include a hole, slot, or aperture which output light beam 125 passes through. As another example, rather than passing through the mirror 115, the output beam 125 may be directed to pass alongside the mirror 115 with a gap (e.g., a gap of width approximately 0.1 mm, 0.5 mm, 1 mm, 2 mm, 5 mm, or 10 mm) between the output beam 125 and an edge of the mirror 115.

In particular embodiments, mirror 115 may provide for output beam 125 and input beam 135 to be substantially coaxial so that the two beams travel along approximately the same optical path (albeit in opposite directions). The input and output beams being substantially coaxial may refer to the beams being at least partially overlapped or sharing a common propagation axis so that input beam 135 and output beam 125 travel along substantially the same optical path (albeit in opposite directions). As an example, output beam 125 and input beam 135 may be parallel to each other to within less than 10 mrad, 5 mrad, 2 mrad, 1 mrad, 0.5 mrad, or 0.1 mrad. As output beam 125 is scanned across a field of regard, the input beam 135 may follow along with the output beam 125 so that the coaxial relationship between the two beams is maintained.

In particular embodiments, lidar system 100 may include a scanner 120 configured to scan an output beam 125 across a field of regard of the lidar system 100. As an example, scanner 120 may include one or more scanning mirrors configured to pivot, rotate, oscillate, or move in an angular manner about one or more rotation axes. The output beam 125 may be reflected by a scanning mirror, and as the scanning mirror pivots or rotates, the reflected output beam 125 may be scanned in a corresponding angular manner. As an example, a scanning mirror may be configured to periodically pivot back and forth over a 30-degree range, which results in the output beam 125 scanning back and forth across a 60-degree range (e.g., a Θ-degree rotation by a scanning mirror results in a 20-degree angular scan of output beam 125).

In particular embodiments, a scanning mirror (which may be referred to as a scan mirror) may be attached to or mechanically driven by a scanner actuator or mechanism which pivots or rotates the mirror over a particular angular range (e.g., over a 5° angular range, 30° angular range, 60° angular range, 120° angular range, 360° angular range, or any other suitable angular range). A scanner actuator or mechanism configured to pivot or rotate a mirror may include a galvanometer scanner, a resonant scanner, a piezoelectric actuator, a voice coil motor, an electric motor (e.g., a DC motor, a brushless DC motor, a synchronous electric motor, or a stepper motor), a microelectromechanical systems (MEMS) device, or any other suitable actuator or mechanism. As an example, a scanner 120 may include a scanning mirror attached to a galvanometer scanner configured to pivot back and forth over a 1° to 30° angular range. As another example, a scanner 120 may include a scanning mirror that is attached to or is part of a MEMS device configured to scan over a 1° to 30° angular range. As another example, a scanner 120 may include a polygon mirror configured to rotate continuously in the same direction (e.g., rather than pivoting back and forth, the polygon mirror continuously rotates 360 degrees in a clockwise or counterclockwise direction). The polygon mirror may be coupled or attached to a synchronous motor configured to rotate the polygon mirror at a substantially fixed rotational frequency (e.g., a rotational frequency of approximately 1 Hz, 10 Hz, 50 Hz, 100 Hz, 500 Hz, or 1,000 Hz).

In particular embodiments, scanner 120 may be configured to scan the output beam 125 (which may include at least a portion of the light emitted by light source 110) across a field of regard of the lidar system 100. A field of regard (FOR) of a lidar system 100 may refer to an area, region, or angular range over which the lidar system 100 may be configured to scan or capture distance information. As an example, a lidar system 100 with an output beam 125 with a 30-degree scanning range may be referred to as having a 30-degree angular field of regard. As another example, a lidar system 100 with a scanning mirror that rotates over a 30-degree range may produce an output beam 125 that scans across a 60-degree range (e.g., a 60-degree FOR). In particular embodiments, lidar system 100 may have a FOR of approximately 10°, 20°, 40°, 60°, 120°, 360°, or any other suitable FOR.

In particular embodiments, scanner 120 may be configured to scan the output beam 125 horizontally and vertically, and lidar system 100 may have a particular FOR along the horizontal direction and another particular FOR along the vertical direction. As an example, lidar system 100 may have a horizontal FOR of 10° to 120° and a vertical FOR of 2° to 45°. In particular embodiments, scanner 120 may include a first scan mirror and a second scan mirror, where the first scan mirror directs the output beam 125 toward the second scan mirror, and the second scan mirror directs the output beam 125 downrange from the lidar system 100. As an example, the first scan mirror may scan the output beam 125 along a first direction, and the second scan mirror may scan the output beam 125 along a second direction that is different from the first direction (e.g., the second direction may be substantially orthogonal to the first direction). As another example, the first scan mirror may scan the output beam 125 along a substantially horizontal direction, and the second scan mirror may scan the output beam 125 along a substantially vertical direction (or vice versa). As another example, the first and second scan mirrors may each be driven by galvanometer scanners. As another example, the first or second scan mirror may include a polygon mirror driven by an electric motor. In particular embodiments, scanner 120 may be referred to as a beam scanner, optical scanner, or laser scanner.

In particular embodiments, one or more scanning mirrors may be communicatively coupled to controller 150 which may control the scanning mirror(s) so as to guide the output beam 125 in a desired direction downrange or along a desired scan pattern. In particular embodiments, a scan pattern may refer to a pattern or path along which the output beam 125 is directed. As an example, scanner 120 may include two scanning mirrors configured to scan the output beam 125 across a 60° horizontal FOR and a 20° vertical FOR. The two scanner mirrors may be controlled to follow a scan path that substantially covers the 60°×20° FOR. As an example, the scan path may result in a point cloud with pixels that substantially cover the 60°×20° FOR. The pixels may be approximately evenly distributed across the 60°×20° FOR. Alternatively, the pixels may have a particular nonuniform distribution (e.g., the pixels may be distributed across all or a portion of the 60°×20° FOR, and the pixels may have a higher density in one or more particular regions of the 60°×20° FOR).

In particular embodiments, a lidar system 100 may include a scanner 120 with a solid-state scanning device. A solid-state scanning device may refer to a scanner 120 that scans an output beam 125 without the use of moving parts (e.g., without the use of a mechanical scanner, such as a mirror that rotates or pivots). For example, a solid-state scanner 120 may include one or more of the following: an optical phased array scanning device; a liquid-crystal scanning device; or a liquid lens scanning device. A solid-state scanner 120 may be an electrically addressable device that scans an output beam 125 along one axis (e.g., horizontally) or along two axes (e.g., horizontally and vertically). In particular embodiments, a scanner 120 may include a solid-state scanner and a mechanical scanner. For example, a scanner 120 may include an optical phased array scanner configured to scan an output beam 125 in one direction and a galvanometer scanner that scans the output beam 125 in an orthogonal direction. The optical phased array scanner may scan the output beam relatively rapidly in a horizontal direction across the field of regard (e.g., at a scan rate of 50 to 1,000 scan lines per second), and the galvanometer may pivot a mirror at a rate of 1-30 Hz to scan the output beam 125 vertically.

In particular embodiments, a lidar system 100 may include a light source 110 configured to emit pulses of light and a scanner 120 configured to scan at least a portion of the emitted pulses of light across a field of regard of the lidar system 100. One or more of the emitted pulses of light may be scattered by a target 130 located downrange from the lidar system 100, and a receiver 140 may detect at least a portion of the pulses of light scattered by the target 130. A receiver 140 may be referred to as a photoreceiver, optical receiver, optical sensor, detector, photodetector, or optical detector. In particular embodiments, lidar system 100 may include a receiver 140 that receives or detects at least a portion of input beam 135 and produces an electrical signal that corresponds to input beam 135. As an example, if input beam 135 includes an optical pulse, then receiver 140 may produce an electrical current or voltage pulse that corresponds to the optical pulse detected by receiver 140. As another example, receiver 140 may include one or more avalanche photodiodes (APDs) or one or more single-photon avalanche diodes (SPADs). As another example, receiver 140 may include one or more PN photodiodes (e.g., a photodiode structure formed by a p-type semiconductor and an n-type semiconductor, where the PN acronym refers to the structure having p-doped and n-doped regions) or one or more PIN photodiodes (e.g., a photodiode structure formed by an undoped intrinsic semiconductor region located between p-type and n-type regions, where the PIN acronym refers to the structure having p-doped, intrinsic, and n-doped regions). An APD, SPAD, PN photodiode, or PIN photodiode may each be referred to as a detector, photodetector, or photodiode. A detector may have an active region or an avalanche-multiplication region that includes silicon, germanium, InGaAs, InAsSb (indium arsenide antimonide), AlAsSb (aluminum arsenide antimonide), or AlInAsSb (aluminum indium arsenide antimonide). The active region may refer to an area over which a detector may receive or detect input light. An active region may have any suitable size or diameter, such as for example, a diameter of approximately 10 μm, 25 μm, 50 μm, 80 μm, 100 μm, 200 μm, 500 μm, 1 mm, 2 mm, or 5 mm.

In particular embodiments, receiver 140 may include electronic circuitry that performs signal amplification, sampling, filtering, signal conditioning, analog-to-digital conversion, time-to-digital conversion, pulse detection, threshold detection, rising-edge detection, or falling-edge detection. As an example, receiver 140 may include a transimpedance amplifier that converts a received photocurrent (e.g., a current produced by an APD in response to a received optical signal) into a voltage signal. The voltage signal may be sent to signal-detection circuitry that produces an analog or digital output signal 145 that corresponds to one or more optical characteristics (e.g., rising edge, falling edge, amplitude, duration, or energy) of a received optical pulse. As an example, the signal-detection circuitry may perform a time-to-digital conversion to produce a digital output signal 145. The electrical output signal 145 may be sent to controller 150 for processing or analysis (e.g., to determine a time-of-flight value corresponding to a received optical pulse).

In particular embodiments, a controller 150 (which may include or may be referred to as a processor, an FPGA, an ASIC, a computer, or a computing system) may be located within a lidar system 100 or outside of a lidar system 100. Alternatively, one or more parts of a controller 150 may be located within a lidar system 100, and one or more other parts of a controller 150 may be located outside a lidar system 100. In particular embodiments, one or more parts of a controller 150 may be located within a receiver 140 of a lidar system 100, and one or more other parts of a controller 150 may be located in other parts of the lidar system 100. For example, a receiver 140 may include an FPGA or ASIC configured to process an output electrical signal from the receiver 140, and the processed signal may be sent to a computing system located elsewhere within the lidar system 100 or outside the lidar system 100. In particular embodiments, a controller 150 may include any suitable arrangement or combination of logic circuitry, analog circuitry, or digital circuitry.

In particular embodiments, controller 150 may be electrically coupled or communicatively coupled to light source 110, scanner 120, or receiver 140. As an example, controller 150 may receive electrical trigger pulses or edges from light source 110, where each pulse or edge corresponds to the emission of an optical pulse by light source 110. As another example, controller 150 may provide instructions, a control signal, or a trigger signal to light source 110 indicating when light source 110 should produce optical pulses. Controller 150 may send an electrical trigger signal that includes electrical pulses, where each electrical pulse results in the emission of an optical pulse by light source 110. In particular embodiments, the frequency, period, duration, pulse energy, peak power, average power, or wavelength of the optical pulses produced by light source 110 may be adjusted based on instructions, a control signal, or trigger pulses provided by controller 150. In particular embodiments, controller 150 may be coupled to light source 110 and receiver 140, and controller 150 may determine a time-of-flight value for an optical pulse based on timing information associated with when the pulse was emitted by light source 110 and when a portion of the pulse (e.g., input beam 135) was detected or received by receiver 140. In particular embodiments, controller 150 may include circuitry that performs signal amplification, sampling, filtering, signal conditioning, analog-to-digital conversion, time-to-digital conversion, pulse detection, threshold detection, rising-edge detection, or falling-edge detection.

In particular embodiments, lidar system 100 may include one or more processors (e.g., a controller 150) configured to determine a distance D from the lidar system 100 to a target 130 based at least in part on a round-trip time of flight for an emitted pulse of light to travel from the lidar system 100 to the target 130 and back to the lidar system 100. The target 130 may be at least partially contained within a field of regard of the lidar system 100 and located a distance D from the lidar system 100 that is less than or equal to an operating range (R_{OP}) of the lidar system 100. In particular embodiments, an operating range (which may be referred to as an operating distance) of a lidar system 100 may refer to a distance over which the lidar system 100 is configured to sense or identify targets 130 located within a field of regard of the lidar system 100. The operating range of lidar system 100 may be any suitable distance, such as for example, 25 m, 50 m, 100 m, 200 m, 250 m, 500 m, or 1 km. As an example, a lidar system 100 with a 200-m operating range may be configured to sense or identify various targets 130 located up to 200 m away from the lidar system 100. The operating range R_{OP} of a lidar system 100 may be related to the time τ between the emission of successive optical signals by the expression R_{OP}=c·τ/2. For a lidar system 100 with a 200-m operating range (R_{OP}=200 m), the time τ between successive pulses (which may be referred to as a pulse period, a pulse repetition interval (PRI), or a time period between pulses) is approximately 2·R_{OP}/c≅1.33 μs. The pulse period τ may also correspond to the time of flight for a pulse to travel to and from a target 130 located a distance R_{OP} from the lidar system 100. Additionally, the pulse period τ may be related to the pulse repetition frequency (PRF) by the expression τ=1/PRF. For example, a pulse period of 1.33 μs corresponds to a PRF of approximately 752 kHz.

In particular embodiments, a lidar system 100 may be used to determine the distance to one or more downrange targets 130. By scanning the lidar system 100 across a field of regard, the system may be used to map the distance to a number of points within the field of regard. Each of these depth-mapped points may be referred to as a pixel or a voxel. A collection of pixels captured in succession (which may be referred to as a depth map, a point cloud, or a frame) may be rendered as an image or may be analyzed to identify or detect objects or to determine a shape or distance of objects within the FOR. As an example, a point cloud may cover a field of regard that extends 60° horizontally and 15° vertically, and the point cloud may include a frame of 100-2000 pixels in the horizontal direction by 4-400 pixels in the vertical direction.

In particular embodiments, lidar system 100 may be configured to repeatedly capture or generate point clouds of a field of regard at any suitable frame rate between approximately 0.1 frames per second (FPS) and approximately 1,000 FPS. As an example, lidar system 100 may generate point clouds at a frame rate of approximately 0.1 FPS, 0.5 FPS, 1 FPS, 2 FPS, 5 FPS, 10 FPS, 20 FPS, 100 FPS, 500 FPS, or 1,000 FPS. As another example, lidar system 100 may be configured to produce optical pulses at a rate of 5×10⁵ pulses/second (e.g., the system may determine 500,000 pixel distances per second) and scan a frame of 1000×50 pixels (e.g., 50,000 pixels/frame), which corresponds to a point-cloud frame rate of 10 frames per second (e.g., 10 point clouds per second). In particular embodiments, a point-cloud frame rate may be substantially fixed, or a point-cloud frame rate may be dynamically adjustable. As an example, a lidar system 100 may capture one or more point clouds at a particular frame rate (e.g., 1 Hz) and then switch to capture one or more point clouds at a different frame rate (e.g., 10 Hz). A slower frame rate (e.g., 1 Hz) may be used to capture one or more high-resolution point clouds, and a faster frame rate (e.g., 10 Hz) may be used to rapidly capture multiple lower-resolution point clouds.

In particular embodiments, a lidar system 100 may be configured to sense, identify, or determine distances to one or more targets 130 within a field of regard. As an example, a lidar system 100 may determine a distance to a target 130, where all or part of the target 130 is contained within a field of regard of the lidar system 100. All or part of a target 130 being contained within a FOR of the lidar system 100 may refer to the FOR overlapping, encompassing, or enclosing at least a portion of the target 130. In particular embodiments, target 130 may include all or part of an object that is moving or stationary relative to lidar system 100. As an example, target 130 may include all or a portion of a person, vehicle, motorcycle, truck, train, bicycle, wheelchair, pedestrian, animal, road sign, traffic light, lane marking, road-surface marking, parking space, pylon, guard rail, traffic barrier, pothole, railroad crossing, obstacle in or near a road, curb, stopped vehicle on or beside a road, utility pole, house, building, trash can, mailbox, tree, any other suitable object, or any suitable combination of all or part of two or more objects. In particular embodiments, a target may be referred to as an object.

In particular embodiments, light source 110, scanner 120, and receiver 140 may be packaged together within a single housing, where a housing may refer to a box, case, or enclosure that holds or contains all or part of a lidar system 100. As an example, a lidar-system enclosure may contain a light source 110, mirror 115, scanner 120, and receiver 140 of a lidar system 100. Additionally, the lidar-system enclosure may include a controller 150. The lidar-system enclosure may also include one or more electrical connections for conveying electrical power or electrical signals to or from the enclosure. In particular embodiments, one or more components of a lidar system 100 may be located remotely from a lidar-system enclosure. As an example, all or part of light source 110 may be located remotely from a lidar-system enclosure, and pulses of light produced by the light source 110 may be conveyed to the enclosure via optical fiber. As another example, all or part of a controller 150 may be located remotely from a lidar-system enclosure.

In particular embodiments, light source 110 may include an eye-safe laser, or lidar system 100 may be classified as an eye-safe laser system or laser product. An eye-safe laser, laser system, or laser product may refer to a system that includes a laser with an emission wavelength, average power, peak power, peak intensity, pulse energy, beam size, beam divergence, exposure time, or scanned output beam such that emitted light from the system presents little or no possibility of causing damage to a person's eyes. As an example, light source 110 or lidar system 100 may be classified as a Class 1 laser product (as specified by the 60825-1:2014 standard of the International Electrotechnical Commission (IEC)) or a Class I laser product (as specified by Title 21, Section 1040.10 of the United States Code of Federal Regulations (CFR)) that is safe under all conditions of normal use. In particular embodiments, lidar system 100 may be an eye-safe laser product (e.g., with a Class 1 or Class I classification) configured to operate at any suitable wavelength between approximately 900 nm and approximately 2100 nm. As an example, lidar system 100 may include a laser with an operating wavelength between approximately 1200 nm and approximately 1400 nm or between approximately 1400 nm and approximately 1600 nm, and the laser or the lidar system 100 may be operated in an eye-safe manner. As another example, lidar system 100 may be an eye-safe laser product that includes a scanned laser with an operating wavelength between approximately 900 nm and approximately 1700 nm. As another example, lidar system 100 may be a Class 1 or Class I laser product that includes a laser diode, fiber laser, or solid-state laser with an operating wavelength between approximately 1200 nm and approximately 1600 nm. As another example, lidar system 100 may have operating wavelengths between approximately 1500 nm and approximately 1550 nm.

In particular embodiments, one or more lidar systems 100 may be integrated into a vehicle. As an example, multiple lidar systems 100 may be integrated into a car to provide a complete 360-degree horizontal FOR around the car. As another example, 2-10 lidar systems 100, each system having a 45-degree to 180-degree horizontal FOR, may be combined together to form a sensing system that provides a point cloud covering a 360-degree horizontal FOR. The lidar systems 100 may be oriented so that adjacent FORs have an amount of spatial or angular overlap to allow data from the multiple lidar systems 100 to be combined or stitched together to form a single or continuous 360-degree point cloud. As an example, the FOR of each lidar system 100 may have approximately 1-30 degrees of overlap with an adjacent FOR. In particular embodiments, a vehicle may refer to a mobile machine configured to transport people or cargo. For example, a vehicle may include, may take the form of, or may be referred to as a car, automobile, motor vehicle, truck, bus, van, trailer, off-road vehicle, farm vehicle, lawn mower, construction equipment, forklift, robot, golf cart, motorhome, taxi, motorcycle, scooter, bicycle, skateboard, train, snowmobile, watercraft (e.g., a ship or boat), aircraft (e.g., a fixed-wing aircraft, helicopter, or dirigible), unmanned aerial vehicle (e.g., drone), or spacecraft. In particular embodiments, a vehicle may include an internal combustion engine or an electric motor that provides propulsion for the vehicle.

In particular embodiments, one or more lidar systems 100 may be included in a vehicle as part of an advanced driver assistance system (ADAS) to assist a driver of the vehicle in operating the vehicle. For example, a lidar system 100 may be part of an ADAS that provides information (e.g., about the surrounding environment) or feedback to a driver (e.g., to alert the driver to potential problems or hazards) or that automatically takes control of part of a vehicle (e.g., a braking system or a steering system) to avoid collisions or accidents. A lidar system 100 may be part of a vehicle ADAS that provides adaptive cruise control, automated braking, automated parking, collision avoidance, alerts the driver to hazards or other vehicles, maintains the vehicle in the correct lane, or provides a warning if an object or another vehicle is in a blind spot.

In particular embodiments, one or more lidar systems 100 may be integrated into a vehicle as part of an autonomous-vehicle driving system. As an example, a lidar system 100 may provide information about the surrounding environment to a driving system of an autonomous vehicle. An autonomous-vehicle driving system may be configured to guide the autonomous vehicle through an environment surrounding the vehicle and toward a destination. An autonomous-vehicle driving system may include one or more computing systems that receive information from a lidar system 100 about the surrounding environment, analyze the received information, and provide control signals to the vehicle's driving systems (e.g., steering mechanism, accelerator, brakes, lights, or turn signals). As an example, a lidar system 100 integrated into an autonomous vehicle may provide an autonomous-vehicle driving system with a point cloud every 0.1 seconds (e.g., the point cloud has a 10 Hz update rate, representing 10 frames per second). The autonomous-vehicle driving system may analyze the received point clouds to sense or identify targets 130 and their respective locations, distances, or speeds, and the autonomous-vehicle driving system may update control signals based on this information. As an example, if lidar system 100 detects a vehicle ahead that is slowing down or stopping, the autonomous-vehicle driving system may send instructions to release the accelerator and apply the brakes.

In particular embodiments, an autonomous vehicle may be referred to as an autonomous car, driverless car, self-driving car, robotic car, or unmanned vehicle. In particular embodiments, an autonomous vehicle may refer to a vehicle configured to sense its environment and navigate or drive with little or no human input. As an example, an autonomous vehicle may be configured to drive to any suitable location and control or perform all safety-critical functions (e.g., driving, steering, braking, parking) for the entire trip, with the driver not expected to control the vehicle at any time. As another example, an autonomous vehicle may allow a driver to safely turn their attention away from driving tasks in particular environments (e.g., on freeways), or an autonomous vehicle may provide control of a vehicle in all but a few environments, requiring little or no input or attention from the driver.

In particular embodiments, an autonomous vehicle may be configured to drive with a driver present in the vehicle, or an autonomous vehicle may be configured to operate the vehicle with no driver present. As an example, an autonomous vehicle may include a driver's seat with associated controls (e.g., steering wheel, accelerator pedal, and brake pedal), and the vehicle may be configured to drive with no one seated in the driver's seat or with little or no input from a person seated in the driver's seat. As another example, an autonomous vehicle may not include any driver's seat or associated driver's controls, and the vehicle may perform substantially all driving functions (e.g., driving, steering, braking, parking, and navigating) without human input. As another example, an autonomous vehicle may be configured to operate without a driver (e.g., the vehicle may be configured to transport human passengers or cargo without a driver present in the vehicle). As another example, an autonomous vehicle may be configured to operate without any human passengers (e.g., the vehicle may be configured for transportation of cargo without having any human passengers onboard the vehicle).

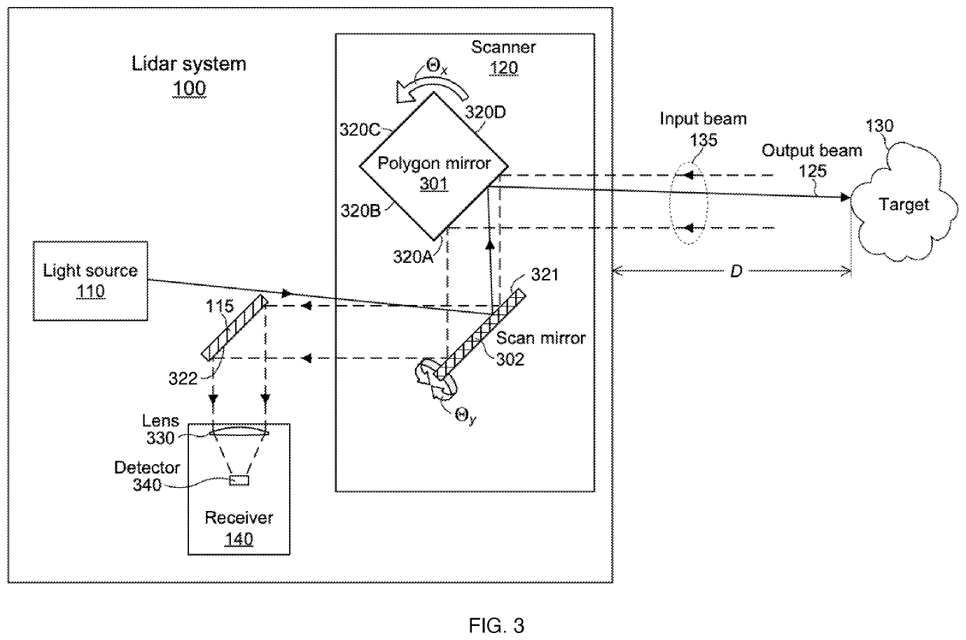

In particular embodiments, an optical signal (which may be referred to as a light signal, a light waveform, an optical waveform, an output beam, or emitted light) may include pulses of light, CW light, amplitude-modulated light, frequency-modulated (FM) light, or any suitable combination thereof. For example, a lidar system 100 as described or illustrated herein may be a pulsed lidar system and may include a light source 110 that produces pulses of light. The pulsed lidar system 100 may include a light source 110 that emits an output beam 125 with optical pulses having one or more of the following optical characteristics: a wavelength between 900 nm and 2100 nm (e.g., a wavelength of approximately 905 nm, a wavelength between 1500 nm and 1510 nm, a wavelength between 1400 nm and 1600 nm, or any other suitable operating wavelength between 900 nm and 2100 nm); a pulse energy between 0.01 μJ and 100 μJ; a pulse repetition frequency between 80 kHz and 10 MHz; and a pulse duration between 1 ns and 100 ns. For example, the light source 110 in FIG. 1 or FIG. 3 may emit an output beam 125 with optical pulses having a wavelength of approximately 1550 nm, a pulse energy of approximately 0.5 μJ, a pulse repetition frequency of approximately 600 kHz, and a pulse duration of approximately 5 ns. Although this disclosure describes or illustrates example embodiments of lidar systems 100 or light sources 110 that produce optical signals that include pulses of light, the embodiments described or illustrated herein may also be applied, where appropriate, to other types of optical signals, including continuous-wave (CW) light, amplitude-modulated optical signals, or frequency-modulated optical signals. For example, a lidar system 100 may be configured to operate as a frequency-modulated continuous-wave (FMCW) lidar system and may include a light source 110 that produces CW light or a frequency-modulated optical signal.

In particular embodiments, a lidar system 100 may be an FMCW lidar system where the emitted light from the light source 110 (e.g., output beam 125 in FIG. 1 or FIG. 3) includes frequency-modulated light. A pulsed lidar system is a type of lidar system 100 in which the light source 110 emits pulses of light, and the distance to a remote target 130 is determined based on the round-trip time-of-flight for a pulse of light to travel to the target 130 and back. Another type of lidar system 100 is a frequency-modulated lidar system, which may be referred to as a frequency-modulated continuous-wave (FMCW) lidar system. An FMCW lidar system uses frequency-modulated light to determine the distance to a remote target 130 based on a frequency of received light (which includes emitted light scattered by the remote target) relative to a frequency of local-oscillator (LO) light. A round-trip time for the emitted light to travel to a target 130 and back to the lidar system may correspond to a frequency difference between the received scattered light and the LO light. A larger frequency difference may correspond to a longer round-trip time and a greater distance to the target 130.

A light source 110 for an FMCW lidar system may include (i) a direct-emitter laser diode, (ii) a seed laser diode followed by an SOA, (iii) a seed laser diode followed by a fiber-optic amplifier, or (iv) a seed laser diode followed by an SOA and then a fiber-optic amplifier. A seed laser diode or a direct-emitter laser diode may be operated in a CW manner (e.g., by driving the laser diode with a substantially constant DC current), and a frequency modulation may be provided by an external modulator (e.g., an electro-optic phase modulator may apply a frequency modulation to seed-laser light). Alternatively, a frequency modulation may be produced by applying a current modulation to a seed laser diode or a direct-emitter laser diode. The current modulation (which may be provided along with a DC bias current) may produce a corresponding refractive-index modulation in the laser diode, which results in a frequency modulation of the light emitted by the laser diode. The current-modulation component (and the corresponding frequency modulation) may have any suitable frequency or shape (e.g., piecewise linear, sinusoidal, triangle-wave, or sawtooth). For example, the current-modulation component (and the resulting frequency modulation of the emitted light) may increase or decrease monotonically over a particular time interval. As another example, the current-modulation component may include a triangle or sawtooth wave with an electrical current that increases or decreases linearly over a particular time interval, and the light emitted by the laser diode may include a corresponding frequency modulation in which the optical frequency increases or decreases approximately linearly over the particular time interval. For example, a light source 110 that emits light with a linear frequency change of 200 MHz over a 2-μs time interval may be referred to as having a frequency modulation m of 10¹⁴ Hz/s (or, 100 MHz/μs).

In addition to producing frequency-modulated emitted light, a light source 110 may also produce frequency-modulated local-oscillator (LO) light. The LO light may be coherent with the emitted light, and the frequency modulation of the LO light may match that of the emitted light. The LO light may be produced by splitting off a portion of the emitted light prior to the emitted light exiting the lidar system. Alternatively, the LO light may be produced by a seed laser diode or a direct-emitter laser diode that is part of the light source 110. For example, the LO light may be emitted from the back facet of a seed laser diode or a direct-emitter laser diode, or the LO light may be split off from the seed light emitted from the front facet of a seed laser diode. The received light (e.g., emitted light that is scattered by a target 130) and the LO light may each be frequency modulated, with a frequency difference or offset that corresponds to the distance to the target 130. For a linearly chirped light source (e.g., a frequency modulation that produces a linear change in frequency with time), the larger the frequency difference is between the received light and the LO light, the farther away the target 130 is located.

A frequency difference between received light and LO light may be determined by mixing the received light with the LO light (e.g., by coupling the two beams onto a detector 340 of a receiver 140 so they are coherently mixed together at the detector) and determining the resulting beat frequency. For example, a photocurrent signal produced by an APD may include a beat signal resulting from the coherent mixing of the received light and the LO light, and a frequency of the beat signal may correspond to the frequency difference between the received light and the LO light. The photocurrent signal from an APD (or a voltage signal that corresponds to the photocurrent signal) may be analyzed using a frequency-analysis technique (e.g., a fast Fourier transform (FFT) technique) to determine the frequency of the beat signal. If a linear frequency modulation m (e.g., in units of Hz/s) is applied to a CW laser, then the round-trip time T may be related to the frequency difference Δf between the received scattered light and the LO light by the expression T=Δf/m. Additionally, the distance D from the target 130 to the lidar system 100 may be expressed as D=(Δf/m)·c/2, where c is the speed of light. For example, for a light source 110 with a linear frequency modulation of 10¹⁴ Hz/s, if a frequency difference (between the received scattered light and the LO light) of 33 MHz is measured, then this corresponds to a round-trip time of approximately 330 ns and a distance to the target of approximately 50 meters. As another example, a frequency difference of 133 MHz corresponds to a round-trip time of approximately 1.33 μs and a distance to the target of approximately 200 meters.

In particular embodiments, a receiver or processor of an FMCW lidar system may determine a frequency difference between received scattered light and LO light, and a distance to a target 130 may be determined based on the frequency difference. The frequency difference Δf between received scattered light and LO light corresponds to the round-trip time T (e.g., through the relationship T=Δf/m), and determining the frequency difference may correspond to or may be referred to as determining the round-trip time. For example, a receiver of a FMCW lidar system may determine a frequency difference between received scattered light and LO light, and based on the determined frequency difference, a processor may determine a distance to the target.

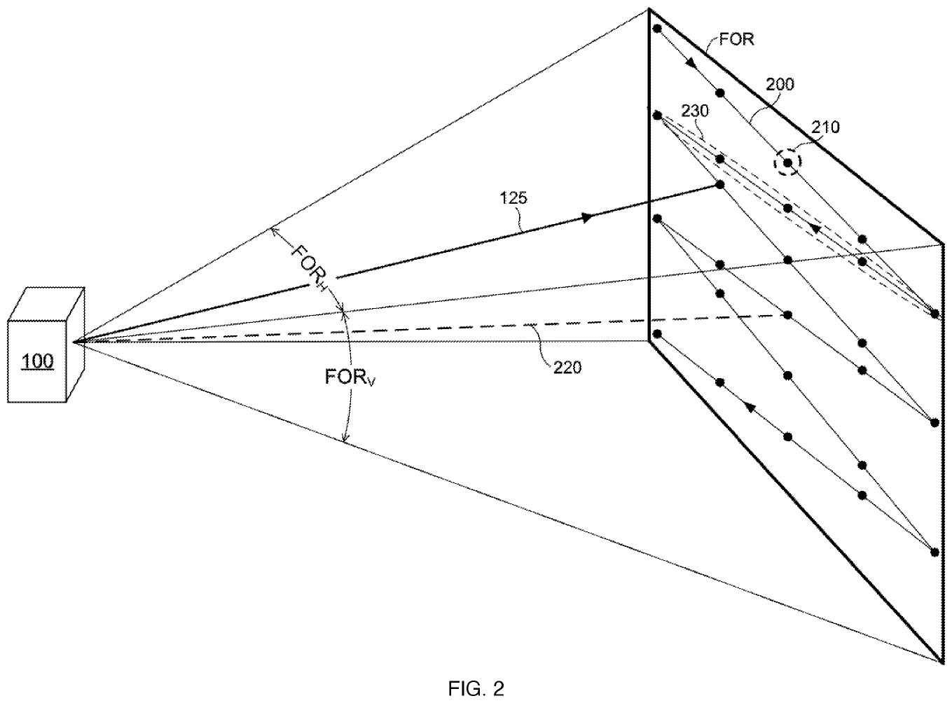

FIG. 2 illustrates an example scan pattern 200 produced by a lidar system 100. A scanner 120 of the lidar system 100 may scan the output beam 125 (which may include multiple emitted optical signals) along a scan pattern 200 that is contained within a field of regard (FOR) of the lidar system 100. A scan pattern 200 (which may be referred to as an optical scan pattern, optical scan path, scan path, or scan) may represent a path or course followed by output beam 125 as it is scanned across all or part of a FOR. Each traversal of a scan pattern 200 may correspond to the capture of a single frame or a single point cloud. In particular embodiments, a lidar system 100 may be configured to scan output optical beam 125 along one or more particular scan patterns 200. In particular embodiments, a scan pattern 200 may scan across any suitable field of regard (FOR) having any suitable horizontal FOR (FOR_{H}) and any suitable vertical FOR (FOR_{V}). For example, a scan pattern 200 may have a field of regard represented by angular dimensions (e.g., FOR_{H}×FOR_{V}) 40°×30°, 90°×40°, or 60°×15°. As another example, a scan pattern 200 may have a FOR_{H} greater than or equal to 10°, 25°, 30°, 40°, 60°, 90°, or 120°. As another example, a scan pattern 200 may have a FOR_{V} greater than or equal to 2°, 5°, 10°, 15°, 20°, 30°, or 45°.

In the example of FIG. 2, reference line 220 represents a center of the field of regard of scan pattern 200. In particular embodiments, reference line 220 may have any suitable orientation, such as for example, a horizontal angle of 0° (e.g., reference line 220 may be oriented straight ahead) and a vertical angle of 0° (e.g., reference line 220 may have an inclination of 0°), or reference line 220 may have a nonzero horizontal angle or a nonzero inclination (e.g., a vertical angle of +10° or −10°). In FIG. 2, if the scan pattern 200 has a 60°×15° field of regard, then scan pattern 200 covers a ±30° horizontal range with respect to reference line 220 and a ±7.5° vertical range with respect to reference line 220. Additionally, optical beam 125 in FIG. 2 has an orientation of approximately −15° horizontal and +3° vertical with respect to reference line 220. Optical beam 125 may be referred to as having an azimuth of −15° and an altitude of +3° relative to reference line 220. In particular embodiments, an azimuth (which may be referred to as an azimuth angle) may represent a horizontal angle with respect to reference line 220, and an altitude (which may be referred to as an altitude angle, elevation, or elevation angle) may represent a vertical angle with respect to reference line 220.

In particular embodiments, a scan pattern 200 may include multiple pixels 210, and each pixel 210 may be associated with one or more laser pulses or one or more distance measurements. Additionally, a scan pattern 200 may include multiple scan lines 230, where each scan line represents one scan across at least part of a field of regard, and each scan line 230 may include multiple pixels 210. In FIG. 2, scan line 230 includes five pixels 210 and corresponds to an approximately horizontal scan across the FOR from right to left, as viewed from the lidar system 100. In particular embodiments, a cycle of scan pattern 200 may include a total of Pₓ×P_{y} pixels 210 (e.g., a two-dimensional distribution of Pₓ by P_{y} pixels). As an example, scan pattern 200 may include a distribution with dimensions of approximately 100-2,000 pixels 210 along a horizontal direction and approximately 4-400 pixels 210 along a vertical direction. As another example, scan pattern 200 may include a distribution of 1,000 pixels 210 along the horizontal direction by 64 pixels 210 along the vertical direction (e.g., the frame size is 1000×64 pixels) for a total of 64,000 pixels per cycle of scan pattern 200. In particular embodiments, the number of pixels 210 along a horizontal direction may be referred to as a horizontal resolution of scan pattern 200, and the number of pixels 210 along a vertical direction may be referred to as a vertical resolution. As an example, scan pattern 200 may have a horizontal resolution of greater than or equal to 100 pixels 210 and a vertical resolution of greater than or equal to 4 pixels 210. As another example, scan pattern 200 may have a horizontal resolution of 100-2,000 pixels 210 and a vertical resolution of 4-400 pixels 210.

In particular embodiments, each pixel 210 may be associated with a distance (e.g., a distance to a portion of a target 130 from which an associated laser pulse was scattered) or one or more angular values. As an example, a pixel 210 may be associated with a distance value and two angular values (e.g., an azimuth and altitude) that represent the angular location of the pixel 210 with respect to the lidar system 100. A distance to a portion of target 130 may be determined based at least in part on a time-of-flight measurement for a corresponding pulse. An angular value (e.g., an azimuth or altitude) may correspond to an angle (e.g., relative to reference line 220) of output beam 125 (e.g., when a corresponding pulse is emitted from lidar system 100) or an angle of input beam 135 (e.g., when an input signal is received by lidar system 100). In particular embodiments, an angular value may be determined based at least in part on a position of a component of scanner 120. As an example, an azimuth or altitude value associated with a pixel 210 may be determined from an angular position of one or more corresponding scanning mirrors of scanner 120.

FIG. 3 illustrates an example lidar system 100 with an example rotating polygon mirror 301. In particular embodiments, a scanner 120 may include a polygon mirror 301 configured to scan output beam 125 along a particular direction. In the example of FIG. 3, scanner 120 includes two scanning mirrors: (1) a polygon mirror 301 that rotates along the Θₓ direction and (2) a scanning mirror 302 that oscillates back and forth along the Θ_{y} direction. The output beam 125 from light source 110, which passes alongside mirror 115, is reflected by reflecting surface 321 of scan mirror 302 and is then reflected by a reflecting surface (e.g., surface 320A, 320B, 320C, or 320D) of polygon mirror 301. Scattered light from a target 130 returns to the lidar system 100 as input beam 135. The input beam 135 reflects from polygon mirror 301, scan mirror 302, and mirror 115, which directs input beam 135 through focusing lens 330 and to the detector 340 of receiver 140. As shown in FIG. 3, scan mirror 302 includes reflecting surface 321 and mirror 115 includes reflecting surface 322. The detector 340 may be a PN photodiode, a PIN photodiode, an APD, an SPAD, or any other suitable detector. A reflecting surface 320 (which may be referred to as a reflective surface) may include a reflective metallic coating (e.g., gold, silver, or aluminum) or a reflective dielectric coating, and the reflecting surface 320 may have any suitable reflectivity R at an operating wavelength of the light source 110 (e.g., R greater than or equal to 70%, 80%, 90%, 95%, 98%, or 99%).

In particular embodiments, a polygon mirror 301 may be configured to rotate along a Θₓ or Θ_{y} direction and scan output beam 125 along a substantially horizontal or vertical direction, respectively. A rotation along a Ox direction may refer to a rotational motion of mirror 301 that results in output beam 125 scanning along a substantially horizontal direction. Similarly, a rotation along a Θ_{y} direction may refer to a rotational motion that results in output beam 125 scanning along a substantially vertical direction. In FIG. 3, mirror 301 is a polygon mirror that rotates along the Θₓ direction and scans output beam 125 along a substantially horizontal direction, and mirror 302 pivots along the Θ_{y} direction and scans output beam 125 along a substantially vertical direction. In particular embodiments, a polygon mirror 301 may be configured to scan output beam 125 along any suitable direction. As an example, a polygon mirror 301 may scan output beam 125 at any suitable angle with respect to a horizontal or vertical direction, such as for example, at an angle of approximately 0°, 10°, 20°, 30°, 45°, 60°, 70°, 80°, or 90° with respect to a horizontal or vertical direction. Additionally, scan mirror 302 may scan the output beam 125 along any suitable direction that is different from the scan direction of the polygon mirror 301. For example, scan mirror 302 may scan the output beam 125 along a direction that is approximately orthogonal to the scan direction of the polygon mirror 301.

In particular embodiments, a polygon mirror 301 may refer to a multi-sided object having reflective surfaces 320 on two or more of its sides or faces. As an example, a polygon mirror may include any suitable number of reflective faces (e.g., 2, 3, 4, 5, 6, 7, 8, or 10 faces), where each face includes a reflective surface 320. A polygon mirror 301 may have a cross-sectional shape of any suitable polygon, such as for example, a triangle (with three reflecting surfaces 320), square (with four reflecting surfaces 320), pentagon (with five reflecting surfaces 320), hexagon (with six reflecting surfaces 320), heptagon (with seven reflecting surfaces 320), or octagon (with eight reflecting surfaces 320). In FIG. 3, the polygon mirror 301 has a substantially square cross-sectional shape and four reflecting surfaces (320A, 320B, 320C, and 320D). The polygon mirror 301 in FIG. 3 may be referred to as a square mirror, a cube mirror, or a four-sided polygon mirror. In FIG. 3, the polygon mirror 301 may have a shape similar to a cube, cuboid, or rectangular prism. Additionally, the polygon mirror 301 may have a total of six sides, where four of the sides include faces with reflective surfaces (320A, 320B, 320C, and 320D).

In particular embodiments, a polygon mirror 301 may be continuously rotated in a clockwise or counter-clockwise rotation direction about a rotation axis of the polygon mirror 301. The rotation axis may correspond to a line that is perpendicular to the plane of rotation of the polygon mirror 301 and that passes through the center of mass of the polygon mirror 301. In FIG. 3, the polygon mirror 301 rotates in the plane of the drawing, and the rotation axis of the polygon mirror 301 is perpendicular to the plane of the drawing. An electric motor may be configured to rotate a polygon mirror 301 at a substantially fixed frequency (e.g., a rotational frequency of approximately 1 Hz (or 1 revolution per second), 10 Hz, 50 Hz, 100 Hz, 500 Hz, or 1,000 Hz). As an example, a polygon mirror 301 may be mechanically coupled to an electric motor (e.g., a synchronous electric motor) which is configured to spin the polygon mirror 301 at a rotational speed of approximately 160 Hz (or, 9600 revolutions per minute (RPM)).

In particular embodiments, output beam 125 may be reflected sequentially from the reflective surfaces 320A, 320B, 320C, and 320D as the polygon mirror 301 is rotated. This results in the output beam 125 being scanned along a particular scan axis (e.g., a horizontal or vertical scan axis) to produce a sequence of scan lines, where each scan line corresponds to a reflection of the output beam 125 from one of the reflective surfaces of the polygon mirror 301. In FIG. 3, the output beam 125 reflects off of reflective surface 320A to produce one scan line. Then, as the polygon mirror 301 rotates, the output beam 125 reflects off of reflective surfaces 320B, 320C, and 320D to produce a second, third, and fourth respective scan line. In particular embodiments, a lidar system 100 may be configured so that the output beam 125 is first reflected from polygon mirror 301 and then from scan mirror 302 (or vice versa). As an example, an output beam 125 from light source 110 may first be directed to polygon mirror 301, where it is reflected by a reflective surface of the polygon mirror 301, and then the output beam 125 may be directed to scan mirror 302, where it is reflected by reflective surface 321 of the scan mirror 302. In the example of FIG. 3, the output beam 125 is reflected from the polygon mirror 301 and the scan mirror 302 in the reverse order. In FIG. 3, the output beam 125 from light source 110 is first directed to the scan mirror 302, where it is reflected by reflective surface 321, and then the output beam 125 is directed to the polygon mirror 301, where it is reflected by reflective surface 320A.

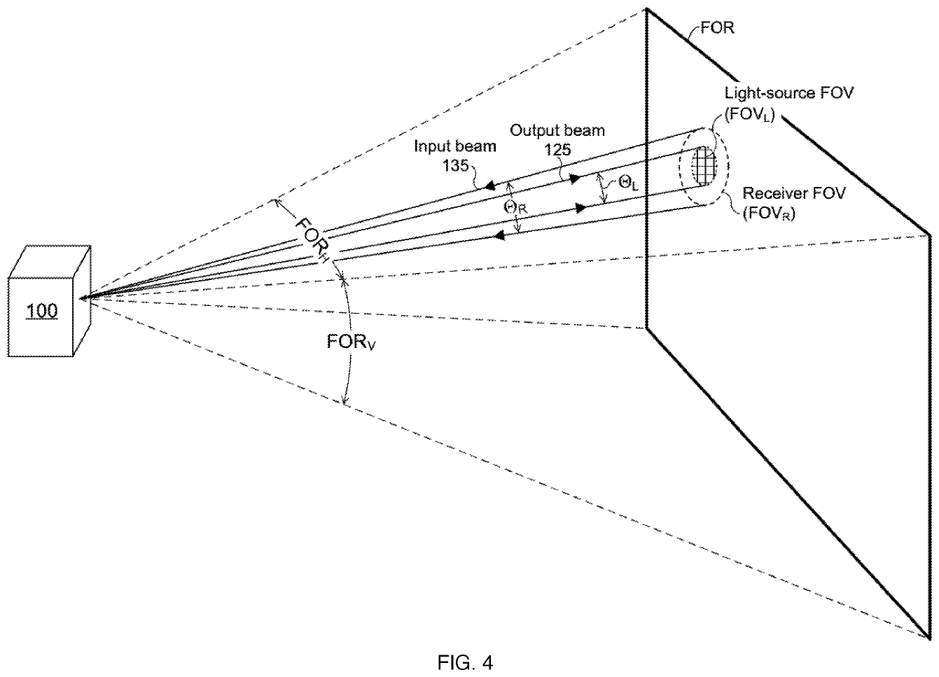

FIG. 4 illustrates an example light-source field of view (FOV_{L}) and receiver field of view (FOV_{R}) for a lidar system 100. A light source 110 of lidar system 100 may emit pulses of light as the FOV_{L} and FOV_{R} are scanned by scanner 120 across a field of regard (FOR). In particular embodiments, a light-source field of view may refer to an angular cone illuminated by the light source 110 at a particular instant of time. Similarly, a receiver field of view may refer to an angular cone over which the receiver 140 may receive or detect light at a particular instant of time, and any light outside the receiver field of view may not be received or detected. As an example, as the light-source field of view is scanned across a field of regard, a portion of a pulse of light emitted by the light source 110 may be sent downrange from lidar system 100, and the pulse of light may be sent in the direction that the FOV_{L} is pointing at the time the pulse is emitted. The pulse of light may scatter off a target 130, and the receiver 140 may receive and detect a portion of the scattered light that is directed along or contained within the FOV_{R}.

In particular embodiments, scanner 120 may be configured to scan both a light-source field of view and a receiver field of view across a field of regard of the lidar system 100. Multiple pulses of light may be emitted and detected as the scanner 120 scans the FOV_{L} and FOV_{R} across the field of regard of the lidar system 100 while tracing out a scan pattern 200. In particular embodiments, the light-source field of view and the receiver field of view may be scanned synchronously with respect to one another, so that as the FOV_{L} is scanned across a scan pattern 200, the FOV_{R} follows substantially the same path at the same scanning speed. Additionally, the FOV_{L} and FOV_{R} may maintain the same relative position to one another as they are scanned across the field of regard. As an example, the FOV_{L} may be substantially overlapped with or centered inside the FOV_{R} (as illustrated in FIG. 4), and this relative positioning between FOV_{L} and FOV_{R} may be maintained throughout a scan. As another example, the FOV_{R} may lag behind the FOV_{L} by a particular, fixed amount throughout a scan (e.g., the FOV_{R} may be offset from the FOV_{L} in a direction opposite the scan direction).

In particular embodiments, the FOV_{L} may have an angular size or extent Θ_{L} that is substantially the same as or that corresponds to the divergence of the output beam 125, and the FOV_{R} may have an angular size or extent Θ_{R} that corresponds to an angle over which the receiver 140 may receive and detect light. In particular embodiments, the receiver field of view may be any suitable size relative to the light-source field of view. As an example, the receiver field of view may be smaller than, substantially the same size as, or larger than the angular extent of the light-source field of view. In particular embodiments, the light-source field of view may have an angular extent of less than or equal to 50 milliradians, and the receiver field of view may have an angular extent of less than or equal to 50 milliradians. The FOV_{L} may have any suitable angular extent Θ_{L}, such as for example, approximately 0.1 mrad, 0.2 mrad, 0.5 mrad, 1 mrad, 1.5 mrad, 2 mrad, 3 mrad, 5 mrad, 10 mrad, 20 mrad, 40 mrad, or 50 mrad. Similarly, the FOV_{R} may have any suitable angular extent Θ_{R}, such as for example, approximately 0.1 mrad, 0.2 mrad, 0.5 mrad, 1 mrad, 1.5 mrad, 2 mrad, 3 mrad, 5 mrad, 10 mrad, 20 mrad, 40 mrad, or 50 mrad. In particular embodiments, the light-source field of view and the receiver field of view may have approximately equal angular extents. As an example, Θ_{L} and Θ_{R} may both be approximately equal to 1 mrad, 2 mrad, or 4 mrad. In particular embodiments, the receiver field of view may be larger than the light-source field of view, or the light-source field of view may be larger than the receiver field of view. As an example, Θ_{L} may be approximately equal to 3 mrad, and Θ_{R} may be approximately equal to 4 mrad. As another example, Θ_{R} may be approximately K times larger than Θ_{L}, where K is any suitable factor, such as for example, 1.1, 1.2, 1.5, 2, 3, 5, or 10.

In particular embodiments, a pixel 210 may represent or may correspond to a light-source field of view or a receiver field of view. As the output beam 125 propagates from the light source 110, the diameter of the output beam 125 (as well as the size of the corresponding pixel 210) may increase according to the beam divergence Θ_{L}. As an example, if the output beam 125 has a Θ_{L} of 2 mrad, then at a distance of 100 m from the lidar system 100, the output beam 125 may have a size or diameter of approximately 20 cm, and a corresponding pixel 210 may also have a corresponding size or diameter of approximately 20 cm. At a distance of 200 m from the lidar system 100, the output beam 125 and the corresponding pixel 210 may each have a diameter of approximately 40 cm.

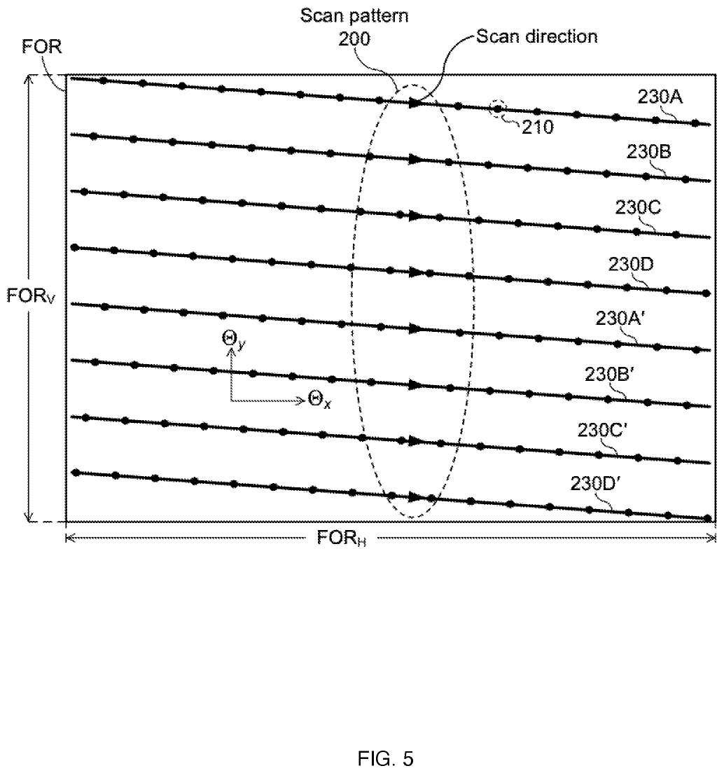

FIG. 5 illustrates an example unidirectional scan pattern 200 that includes multiple pixels 210 and multiple scan lines 230. In particular embodiments, scan pattern 200 may include any suitable number of scan lines 230 (e.g., approximately 1, 2, 5, 10, 20, 50, 100, 500, or 1,000 scan lines), and each scan line 230 of a scan pattern 200 may include any suitable number of pixels 210 (e.g., 1, 2, 5, 10, 20, 50, 100, 200, 500, 1,000, 2,000, or 5,000 pixels). The scan pattern 200 illustrated in FIG. 5 includes eight scan lines 230, and each scan line 230 includes approximately 16 pixels 210. In particular embodiments, a scan pattern 200 where the scan lines 230 are scanned in two directions (e.g., alternately scanning from right to left and then from left to right) may be referred to as a bidirectional scan pattern 200, and a scan pattern 200 where the scan lines 230 are scanned in the same direction may be referred to as a unidirectional scan pattern 200. The scan pattern 200 in FIG. 2 may be referred to as a bidirectional scan pattern, and the scan pattern 200 in FIG. 5 may be referred to as a unidirectional scan pattern 200 where each scan line 230 travels across the FOR in substantially the same direction (e.g., approximately from left to right as viewed from the lidar system 100). In particular embodiments, scan lines 230 of a unidirectional scan pattern 200 may be directed across a FOR in any suitable direction, such as for example, from left to right, from right to left, from top to bottom, from bottom to top, or at any suitable angle (e.g., at a 0°, 5°, 10°, 30°, or 45° angle) with respect to a horizontal or vertical axis. In particular embodiments, each scan line 230 in a unidirectional scan pattern 200 may be a separate line that is not directly connected to a previous or subsequent scan line 230.

In particular embodiments, a unidirectional scan pattern 200 may be produced by a scanner 120 that includes a polygon mirror (e.g., polygon mirror 301 of FIG. 3), where each scan line 230 is associated with a particular reflective surface 320 of the polygon mirror. As an example, reflective surface 320A of polygon mirror 301 in FIG. 3 may produce scan line 230A in FIG. 5. Similarly, as the polygon mirror 301 rotates, reflective surfaces 320B, 320C, and 320D may successively produce scan lines 230B, 230C, and 230D, respectively. Additionally, for a subsequent revolution of the polygon mirror 301, the scan lines 230A′, 230B′, 230C′, and 230D′ may be successively produced by reflections of the output beam 125 from reflective surfaces 320A, 320B, 320C, and 320D, respectively. In particular embodiments, N successive scan lines 230 of a unidirectional scan pattern 200 may correspond to one full revolution of an N-sided polygon mirror. As an example, the four scan lines 230A, 230B, 230C, and 230D in FIG. 5 may correspond to one full revolution of the four-sided polygon mirror 301 in FIG. 3. Additionally, a subsequent revolution of the polygon mirror 301 may produce the next four scan lines 230A′, 230B′, 230C′, and 230D′ in FIG. 5.

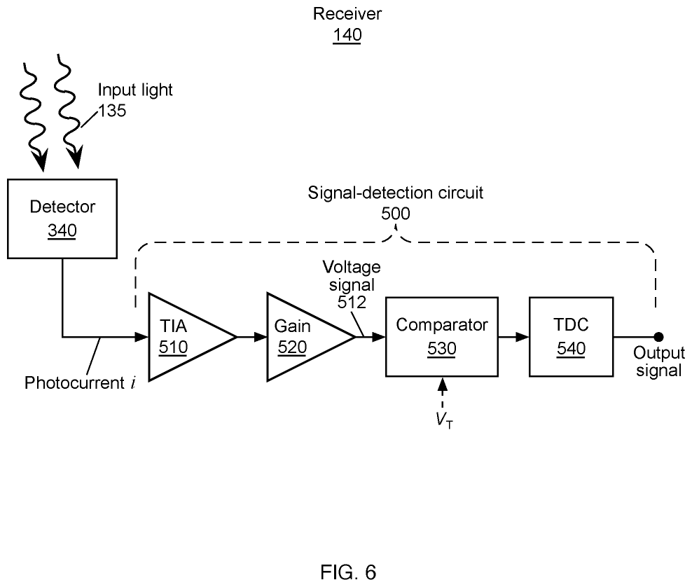

FIG. 6 illustrates an example receiver 140 that includes a detector 340 coupled to a signal-detection circuit 500. In particular embodiments, a signal-detection circuit 500 may include circuitry that receives an electrical-current signal (e.g., photocurrent i) from a detector 340 and performs current-to-voltage conversion, signal amplification, sampling, filtering, signal conditioning, analog-to-digital conversion, time-to-digital conversion, pulse detection, threshold detection, rising-edge detection, or falling-edge detection. The detector 340 may be a PN photodiode, a PIN photodiode, an APD, a SPAD, or any other suitable detector. A signal-detection circuit 500 may be used to determine (i) whether an optical signal (e.g., an optical pulse) has been received by a detector 340 or (ii) a time associated with receipt of an optical signal by a detector 340. A signal-detection circuit 500 may include a transimpedance amplifier (TIA) 510, a voltage-gain circuit 520, a comparator 530, or a time-to-digital converter (TDC) 540. In particular embodiments, a signal-detection circuit 500 may be included in a receiver 140 or a controller 150, or parts of a signal-detection circuit 500 may be included in a receiver 140 and other parts may be included in a controller 150. As an example, a TIA 510 and a voltage-gain circuit 520 may be part of a receiver 140, and a comparator 530 and a TDC 540 may be part of a controller 150 that is coupled to the receiver 140. As another example, a TIA 510, gain circuit 520, comparator 530, and TDC 540 may be part of a receiver 140, and an output signal from the TDC 540 may be supplied to a controller 150.

In particular embodiments, a signal-detection circuit 500 may include a TIA 510 configured to receive a photocurrent signal i from a detector 340 and produce a voltage signal that corresponds to the received photocurrent. As an example, in response to a received optical pulse (e.g., light from an emitted optical pulse that is scattered by a remote target 130), a detector 340 may produce photocurrent i that includes a pulse of electrical current corresponding to the received optical pulse. A TIA 510 may receive the electrical-current pulse from the detector 340 and produce a voltage pulse that corresponds to the received current pulse. In particular embodiments, a TIA 510 may also act as an electronic filter. As an example, a TIA 510 may be configured as a low-pass filter that removes or attenuates high-frequency electrical noise by attenuating signals above a particular frequency (e.g., above 1 MHz, 10 MHz, 20 MHz, 50 MHz, 100 MHz, 200 MHz, 300 MHz, 1 GHz, or any other suitable frequency). In particular embodiments, a signal-detection circuit 500 may include a voltage-gain circuit 520 (which may be referred to as a gain circuit or a voltage amplifier) configured to amplify a voltage signal. As an example, a gain circuit 520 may include one or more voltage-amplification stages that amplify a voltage signal received from a TIA 510. For example, the gain circuit 520 may receive a voltage pulse from a TIA 510, and the gain circuit 520 may amplify the voltage pulse by any suitable amount, such as for example, by a gain of approximately 3 dB, 10 dB, 20 dB, 30 dB, 40 dB, or 50 dB. Additionally, the gain circuit 520 may be configured to also act as an electronic filter to remove or attenuate electrical noise. In particular embodiments, a signal-detection circuit 500 may not include a separate gain circuit 520 (e.g., a TIA 510 may produce a voltage signal 512 that is directly coupled to a comparator 530 without an intervening gain circuit).

In particular embodiments, a signal-detection circuit 500 may include a comparator 530 configured to receive a voltage signal 512 from TIA 510 or gain circuit 520 and produce an electrical-edge signal (e.g., a rising edge or a falling edge) when the received voltage signal rises above or falls below a particular threshold voltage V_{T}. As an example, when a received voltage signal 512 rises above V_{T}, a comparator 530 may produce a rising-edge digital-voltage signal (e.g., a signal that steps from approximately 0 V to approximately 2.5 V, 3.3 V, 5 V, or any other suitable digital-high level). Additionally or alternatively, when a received voltage signal 512 falls below V_{T}, a comparator 530 may produce a falling-edge digital-voltage signal (e.g., a signal that steps down from approximately 2.5 V, 3.3 V, 5 V, or any other suitable digital-high level to approximately 0 V). The voltage signal 512 received by the comparator 530 may be received from a TIA 510 or gain circuit 520 and may correspond to a photocurrent signal i produced by a detector 340. As an example, the voltage signal 512 received by the comparator 530 may include a voltage pulse that corresponds to an electrical-current pulse produced by the detector 340 in response to a received optical pulse. The voltage signal 512 received by the comparator 530 may be an analog signal, and an electrical-edge signal produced by the comparator 530 may be a digital signal.

In particular embodiments, a signal-detection circuit 500 may include a time-to-digital converter (TDC) 540 configured to receive an electrical-edge signal from a comparator 530 and determine an interval of time between emission of a pulse of light by the light source 110 and receipt of the electrical-edge signal. The interval of time may correspond to a round-trip time of flight for an emitted pulse of light to travel from the lidar system 100 to a target 130 and back to the lidar system 100. The portion of the emitted pulse of light that is received by the lidar system 100 (e.g., scattered light from target 130) may be referred to as a received pulse of light. The output of the TDC 540 may include one or more numerical values, where each numerical value (which may be referred to as a numerical time value, a time value, a digital value, or a digital time value) corresponds to a time interval determined by the TDC 540. In particular embodiments, a TDC 540 may have an internal counter or clock with any suitable period, such as for example, 5 ps, 10 ps, 15 ps, 20 ps, 30 ps, 50 ps, 100 ps, 0.5 ns, 1 ns, 2 ns, 5 ns, or 10 ns. As an example, the TDC 540 may have an internal counter or clock with a 20-ps period, and the TDC 540 may determine that an interval of time between emission and receipt of an optical pulse is equal to 25,000 time periods, which corresponds to a time interval of approximately 0.5 microseconds. The TDC 540 may send an output signal that includes the numerical value “25000” to a processor or controller 150 of the lidar system 100. In particular embodiments, a lidar system 100 may include a processor configured to determine a distance from the lidar system 100 to a target 130 based at least in part on an interval of time determined by a TDC 540. As an example, the processor may be an ASIC or FPGA and may be a part of a receiver 140 or controller 150. The processor may receive a numerical value (e.g., “25000”) from the TDC 540, and based on the received value, the processor may determine the distance from the lidar system 100 to a target 130.

In particular embodiments, determining an interval of time between emission and receipt of a pulse of light may be based on determining (1) a time associated with the emission of the pulse by light source 110 or lidar system 100 and (2) a time when scattered light from the pulse is detected by receiver 140. As an example, a TDC 540 may count the number of time periods or clock cycles between an electrical edge associated with emission of a pulse of light and an electrical edge associated with detection of scattered light from the pulse. Determining when scattered light from the pulse is detected by receiver 140 may be based on determining a time for a rising or falling edge (e.g., a rising or falling edge produced by comparator 530) associated with the detected pulse. In particular embodiments, determining a time associated with emission of a pulse of light may be based on an electrical trigger signal. As an example, light source 110 may produce an electrical trigger signal for each pulse of light that is emitted, or an electrical device (e.g., controller 150) may provide a trigger signal to the light source 110 to initiate the emission of each pulse of light. A trigger signal associated with emission of an optical pulse may be provided to TDC 540, and a rising edge or falling edge of the trigger signal may correspond to a time when the optical pulse is emitted. In particular embodiments, a time associated with emission of an optical pulse may be determined based on an optical trigger signal. As an example, a time associated with the emission of a pulse of light may be determined based at least in part on detection of a portion of light from the emitted pulse of light prior to the emitted pulse of light exiting the lidar system 100 and propagating to target 130. The portion of the emitted pulse of light (which may be referred to as an optical trigger pulse) may be detected by a separate detector (e.g., a PIN photodiode or an APD) or by the receiver 140. A portion of light from an emitted pulse of light may be scattered or reflected from a surface (e.g., a surface of a beam splitter or window, or a surface of light source 110, mirror 115, or scanner 120) located within lidar system 100. Some of the scattered or reflected light may be received by a detector 340 of receiver 140, and a signal-detection circuit 500 coupled to the detector 340 may determine that an optical trigger pulse has been received. The time at which the optical trigger pulse was received may be associated with the emission time of the pulse.

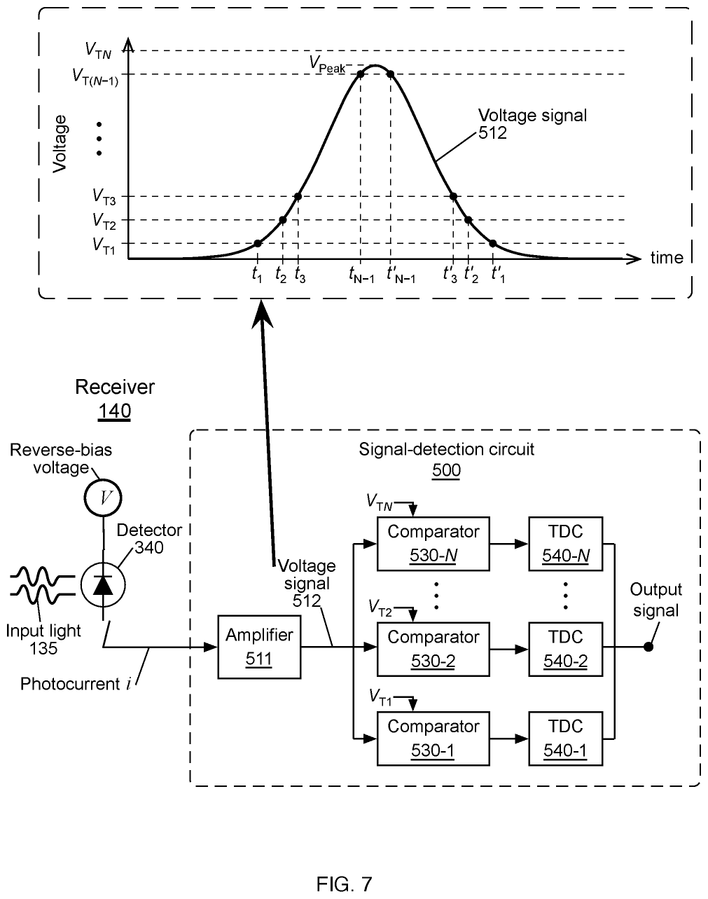

FIG. 7 illustrates an example receiver 140 and an example voltage signal 512 corresponding to a received pulse of light. A light source 110 of a lidar system 100 may emit a pulse of light, and a receiver 140 may be configured to detect input light 135. The input light 135 in FIG. 7 may include a received pulse of light. In particular embodiments, a receiver 140 of a lidar system 100 may include one or more detectors 340, one or more electronic amplifiers 511, one or more comparators 530, or one or more time-to-digital converters (TDCs) 540. The receiver 140 illustrated in FIG. 7 includes a detector 340 configured to receive input light 135 and produce a photocurrent i that corresponds to a received pulse of light (which is part of the input light 135). The photocurrent i produced by the detector 340 may be referred to as a photocurrent signal, electrical-current signal, electrical current, or current. The detector 340 may be a PN photodiode, a PIN photodiode, an APD, a SPAD, or any other suitable detector. The detector 340 may be configured to detect light at a 1200-1600 nm operating wavelength of a lidar system 100.

In FIG. 7, the detector 340 is electrically coupled to a signal-detection circuit 500 (which may be referred to as a pulse-detection circuit). The detector 340 is also electrically coupled to a voltage source that supplies a reverse-bias voltage V to the detector 340. The signal-detection circuit 500 includes an electronic amplifier 511 configured to receive the photocurrent and produce a voltage signal 512 that corresponds to the received photocurrent. For example, the detector 340 may produce a pulse of photocurrent in response to a received pulse of light, and the voltage signal 512 may be an analog voltage pulse that corresponds to the pulse of photocurrent. The amplifier 511 may include a TIA 510 configured to receive the photocurrent i and amplify the photocurrent to produce a voltage signal 512 (e.g., a voltage pulse) that corresponds to the photocurrent signal. Alternatively, the amplifier 511 may include a TIA 510 followed by a voltage-gain circuit 520. The TIA 510 may amplify the photocurrent i to produce an intermediate voltage signal (e.g., a voltage pulse), and the voltage-gain circuit 520 may amplify the intermediate voltage signal to produce a voltage signal 512 (e.g., an amplified voltage pulse). An amplifier 511 or a TIA 510 may include an electronic filter (e.g., a low-pass, high-pass, or bandpass filter) that filters the photocurrent i or the voltage signal 512. The transimpedance gain or amplification of a TIA 510 may be expressed in units of ohms (Ω), or equivalently volts per ampere (V/A). For example, if a TIA 510 has a gain of 100 V/A, then for a photocurrent i with a peak current of 10 μA, the TIA 510 may produce a voltage signal 512 with a corresponding peak voltage of approximately 1 mV.

In FIG. 7, the voltage signal 512 produced by the amplifier 511 is coupled to N comparators (comparators 530-1, 530-2, . . . , 530-N), and each comparator is supplied with a particular threshold or reference voltage (V_{T1}, V_{T2}, . . . , V_{TN}). A signal-detection circuit 500 may include 1, 2, 5, 10, 50, 100, 500, 1000, or any other suitable number of comparators 530. The signal-detection circuit 500 in FIG. 6 includes one comparator 530. In FIG. 7, the signal-detection circuit 500 may include N=10 comparators, and the threshold voltages may be set to 10 values between 0 volts and 1 volt (e.g., V_{T1}=0.1 V, V_{T2}=0.2 V, and V_{T10}=1.0 V). Each comparator may produce an electrical-edge signal (e.g., a rising or falling electrical edge) when the voltage signal 512 rises above or falls below a particular threshold voltage. For example, comparator 530-2 may produce a rising edge when the voltage signal 512 rises above the threshold voltage V_{T2}. Additionally or alternatively, comparator 530-2 may produce a falling edge when the voltage signal 512 falls below the threshold voltage V_{T2}.

The signal-detection circuit 500 in FIG. 7 includes N time-to-digital converters (TDCs 540-1, 540-2, . . . , 540-N), and each comparator is coupled to a TDC 540. Each comparator-TDC pair in FIG. 7 (e.g., comparator 530-1 and TDC 540-1) may be referred to as a threshold detector. A comparator may provide an electrical-edge signal to a corresponding TDC, and the TDC may act as a timer that produces an electrical output signal (e.g., a digital signal, a digital word, or a digital value) that represents a time when the edge signal is received from the comparator. For example, if the voltage signal 512 rises above the threshold voltage V_{T1}, then the comparator 530-1 may produce a rising-edge signal that is supplied to the input of TDC 540-1, and the TDC 540-1 may produce a digital time value corresponding to a time when the edge signal was received by TDC 540-1. The digital time value may be referenced to the time when a pulse of light is emitted by a light source 110, and the digital time value may correspond to or may be used to determine a round-trip time for the pulse of light to travel from a lidar system 100, to a target 130, and back to the lidar system 100. Additionally, if the voltage signal 512 subsequently falls below the threshold voltage V_{T1}, then the comparator 530-1 may produce a falling-edge signal that is supplied to the input of TDC 540-1, and the TDC 540-1 may produce a digital time value corresponding to a time when the edge signal was received by TDC 540-1.

In particular embodiments, an output signal of a signal-detection circuit 500 may include an electrical signal that corresponds to a received pulse of light. For example, the signal-detection output signal in FIG. 7 may be a digital signal that corresponds to the analog voltage signal 512, which in turn corresponds to the photocurrent signal i, which in turn corresponds to a received pulse of light. If an input light signal 135 includes a received pulse of light, the signal-detection circuit 500 may receive a photocurrent i (e.g., a pulse of current) and produce an output signal that corresponds to the received pulse of light. The output signal may include one or more digital time values from each of the TDCs 540 that received one or more edge signals from a comparator 530, and the digital time values may represent the analog voltage signal 512. The output signal from a signal-detection circuit 500 may be sent to a controller 150, and a time of arrival for the received pulse of light (which may be referred to as a time of receipt) may be determined based at least in part on the one or more time values produced by the TDCs. For example, the time of arrival may be determined from a time associated with a peak (e.g., Vₚₑₐₖ) of the voltage signal 512 or from a temporal center (e.g., a centroid or weighted average) of the voltage signal 512. The output signal in FIG. 7 may correspond to the electrical output signal 145 in FIG. 1.

In particular embodiments, a signal-detection output signal may include one or more digital values that correspond to a time interval between (1) a time when a pulse of light is emitted and (2) a time when a received pulse of light is detected by a receiver 140. The output signal in FIG. 7 may include digital values from each of the TDCs that receive an edge signal from a comparator, and each digital value may represent a time interval between the emission of an optical pulse by a light source 110 and the receipt of an edge signal from a comparator. For example, a light source 110 may emit a pulse of light that is scattered by a target 130, and a receiver 140 may receive a portion of the scattered pulse of light as an input pulse of light. When the light source emits the pulse of light, a count value of the TDCs may be reset to zero counts. Alternatively, the TDCs in receiver 140 may accumulate counts continuously over multiple pulse periods (e.g., for 10, 100, 1,000, 10,000, or 100,000 pulse periods), and when a pulse of light is emitted, a TDC count associated with the pulse emission may be stored in memory. After the pulse of light is emitted, the TDCs may continue to accumulate counts that correspond to elapsed time (e.g., the TDCs may count in terms of clock cycles or some fraction of clock cycles).

In FIG. 7, when TDC 540-1 receives an edge signal from comparator 530-1, the TDC 540-1 may produce a digital signal that represents the time interval between emission of the pulse of light and receipt of the edge signal. For example, the digital signal may include a digital value that corresponds to the number of clock cycles that elapsed between emission of the pulse of light and receipt of the edge signal. Alternatively, if the TDC 540-1 accumulates counts over multiple pulse periods, then the digital signal may include a digital value that corresponds to the TDC count at the time of receipt of the edge signal. The signal-detection output signal may include digital values corresponding to one or more times when a pulse of light was emitted and one or more times when a TDC received an edge signal. An output signal from a signal-detection circuit 500 may correspond to a received pulse of light and may include digital values from each of the TDCs that receive an edge signal from a comparator. The output signal may be sent to a controller 150, and the controller may determine a distance D to the target 130 based at least in part on the output signal. Additionally or alternatively, the controller 150 may determine an optical characteristic of a received pulse of light based at least in part on the output signal received from the TDCs of a signal-detection circuit 500.

In particular embodiments, a receiver 140 of a lidar system 100 may include one or more analog-to-digital converters (ADCs). As an example, instead of including multiple comparators and TDCs, a receiver 140 may include an ADC that receives a voltage signal 512 from amplifier 511 and produces a digital representation of the voltage signal 512. Although this disclosure describes or illustrates example receivers 140 that include one or more comparators 530 and one or more TDCs 540, a receiver 140 may additionally or alternatively include one or more ADCs. As an example, in FIG. 7, instead of the N comparators 530 and N TDCs 540, the receiver 140 may include an ADC configured to receive the voltage signal 512 and produce a digital output signal that includes digitized values that correspond to the voltage signal 512.

The example voltage signal 512 illustrated in FIG. 7 corresponds to a received pulse of light. The voltage signal 512 may be an analog signal produced by an electronic amplifier 511 and may correspond to a pulse of light detected by the receiver 140 in FIG. 7. The voltage levels on the y-axis correspond to the threshold voltages V_{T1}, V_{T2}, . . . , V_{TN} of the respective comparators 530-1, 530-2, . . . , 530-N. The time values t₁, t₂, t₃, t_{N-1} correspond to times when the voltage signal 512 exceeds the corresponding threshold voltages, and the time values t′₁, t′₂, t′₃, . . . , t_{N-1} correspond to times when the voltage signal 512 falls below the corresponding threshold voltages. For example, at time t₁ when the voltage signal 512 exceeds the threshold voltage V_{T1}, comparator 530-1 may produce an edge signal, and TDC 540-1 may output a digital value corresponding to the time t₁. Additionally, the TDC 540-1 may output a digital value corresponding to the time t′₁ when the voltage signal 512 falls below the threshold voltage V_{T1}. Alternatively, the receiver 140 may include an additional TDC (not illustrated in FIG. 7) configured to produce a digital value corresponding to time t′₁ when the voltage signal 512 falls below the threshold voltage V_{T1}. The output signal from signal-detection circuit 500 may include one or more digital values that correspond to one or more of the time values t₁, t₂, t₃, . . . , t_{N-1} and t′₁, t′₂, t′₃, . . . , t′_{N-1}. Additionally, the output signal may also include one or more values corresponding to the threshold voltages associated with the time values. Since the voltage signal 512 in FIG. 7 does not exceed the threshold voltage V_{TN}, the corresponding comparator 530-N may not produce an edge signal. As a result, TDC 540-N may not produce a time value, or TDC 540-N may produce a signal indicating that no edge signal was received.

In particular embodiments, an output signal produced by a signal-detection circuit 500 of a receiver 140 may correspond to or may be used to determine an optical characteristic of a received pulse of light detected by the receiver 140. An optical characteristic of a received pulse of light may include a peak optical intensity, a peak optical power, an average optical power, an optical energy, a shape or amplitude, a time of receipt, a temporal center, a round-trip time of flight, or a temporal duration or width of the received pulse of light. One or more of the approaches for determining an optical characteristic of a received pulse of light as described herein may be implemented using a receiver 140 that includes one or more comparators 530 and TDCs 540 or using a receiver 140 that includes one or more ADCs. For example, an optical characteristic of a received pulse of light may be determined from an output signal provided by multiple TDCs 540 of a signal-detection circuit 500 (as illustrated in FIG. 7), or an optical characteristic may be determined from an output signal provided by one or more ADCs of a signal-detection circuit.

A round-trip time of flight (e.g., a time for an emitted pulse of light to travel from the lidar system 100 to a target 130 and back to the lidar system 100) may be determined based on a difference between a time of receipt and a time of emission for a pulse of light, and the distance D to the target 130 may be determined based on the round-trip time of flight. A time of receipt for a received pulse of light may correspond to (i) a time associated with a peak of voltage signal 512 or (ii) a time associated with a temporal center of voltage signal 512. For example, in FIG. 7 a time associated with the peak voltage (Vₚₑₐₖ) may be determined based on the threshold voltage V_{T(N-1)} (e.g., an average of the times t_{N-1} and t′_{N-1} may correspond to the peak-voltage time). As another example, a curve-fit or interpolation operation may be applied to the values of a signal-detection output signal to determine a time associated with the peak voltage. A curve may be fit to the values of a signal-detection output signal to produce a curve that approximates the shape of a received optical pulse, and a time associated with the peak of the curve may correspond to the peak-voltage time. As another example, a curve that is fit to the values of a signal-detection output signal may be used to determine a time associated with a temporal center of voltage signal 512 (e.g., the temporal center may be determined by calculating a centroid or weighted average of the curve).

A duration of a received pulse of light may be determined from a duration or width of a corresponding voltage signal 512. For example, the difference between two time values of a signal-detection output signal may be used to determine a duration of a received pulse of light. In the example of FIG. 7, the duration of the pulse of light corresponding to voltage signal 512 may be determined from the difference (t′₃−t₃), which may correspond to a received pulse of light with a pulse duration of 4 nanoseconds. As another example, a controller 150 may apply a curve-fit or interpolation operation to the values of the signal-detection output signal, and the duration of the pulse of light may be determined based on a width of the curve (e.g., a full width at half maximum of the curve).

In particular embodiments, a temporal correction or offset may be applied to a determined time of emission or time of receipt to account for signal delay within a lidar system 100. For example, there may be a time delay of 2 ns between an electrical trigger signal that initiates emission of a pulse of light and a time when the emitted pulse of light exits the lidar system 100. To account for the 2-ns time delay, a 2-ns offset may be added to an initial time of emission determined by a receiver 140 or a processor of the lidar system 100. For example, a receiver 140 may receive an electrical trigger signal at time t_{TRIG} indicating emission of a pulse of light by light source 110. To compensate for the 2-ns delay between the trigger signal and the pulse of light exiting the lidar system 100, the emission time of the pulse of light may be indicated as (t_{TRIG}+2 ns). Similarly, there may be a 1-ns time delay between a received pulse of light entering the lidar system 100 and a time when electrical edge signals corresponding to the received pulse of light are received by one or more TDCs 540 of a receiver 140. To account for the 1-ns time delay, a 1-ns offset may be subtracted from a determined time of receipt.

In particular embodiments, a processor or a receiver 140 may determine, based on a photocurrent signal i produced by a detector 340, a round-trip time T for a portion of an emitted optical signal to travel to a target 130 and back to a lidar system 100. Additionally, a processor or a receiver 140 may determine a distance D from the lidar system 100 to the target 130 based on the round-trip time T For example, a detector 340 may produce a pulse of photocurrent i in response to a received pulse of light, and a receiver 140 may produce a voltage pulse (e.g., voltage signal 512) corresponding to the pulse of photocurrent. Based on the voltage signal 512, the receiver 140 or a processor may determine a time of receipt for the received pulse of light. Additionally, the receiver 140 or processor may determine a time of emission for a pulse of light (e.g., a time at which the pulse of light was emitted by a light source 110), where the received pulse of light includes scattered light from the emitted pulse of light. For example, based on the time of receipt (T_{R}) and the time of emission (T_{E}), the receiver 140 or processor may determine the round-trip time T (e.g., T=T_{R}−T_{E}), and the distance D may be determined from the expression D=c·T/2.

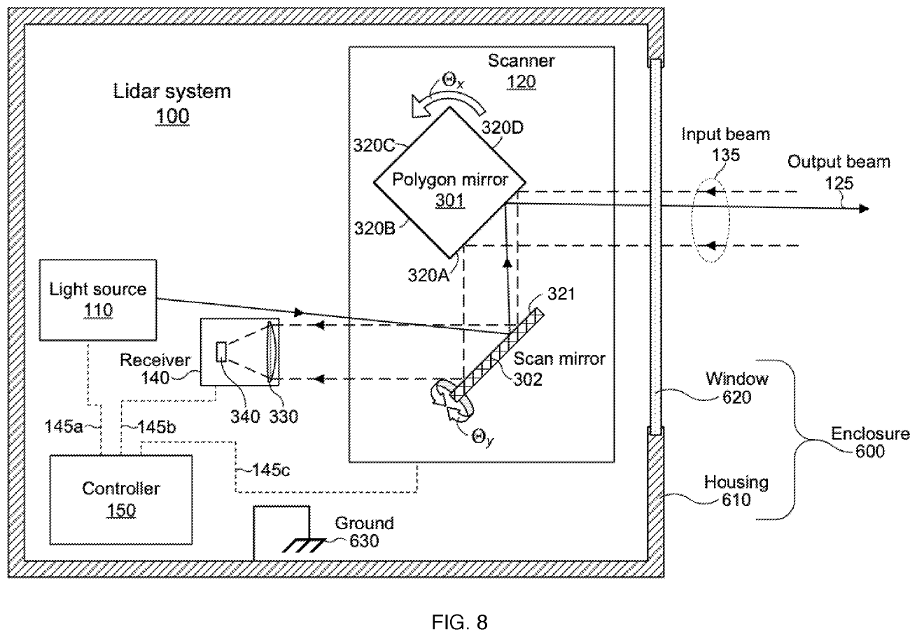

FIG. 8 illustrates an example lidar system contained within an enclosure. In the example shown, lidar system 100 depicts enclosure 600 of lidar system 100. Enclosure 600 is attached to ground 630 and includes both housing 610 and window 620. As shown in FIG. 8, window 620 closes an opening in housing 610 that allows output beam 125 to exit and input beam 135 to enter lidar system 100. In various embodiments, window 620 includes at least a semiconductor window that reduces or suppresses electromagnetic interference (EMI) while maintaining optical transparency. For example, the semiconductor window can be configured to transmit greater than or equal to 90% of an emitted optical signal. In some embodiments, the semiconductor window can be configured to transmit greater than 99% of an emitted optical signal. In various embodiments, window 620 includes multiple windows including a semiconductor window and a second exterior window (not shown). The exterior window can provide protection from the external environment and the semiconductor window can function to at least reduce electromagnetic radiation. In particular embodiments, housing 610 is constructed with an electrically conductive material, such as an electrically conductive metal, and the semiconductor window of window 620 is a semiconductor material doped with a p-type or n-type dopant configured to cause the semiconductor material to have a higher electrical conductivity than an undoped form of the semiconductor material. In some embodiments, the lidar system of FIG. 8 is lidar system 100 of FIGS. 1-4.

In various embodiments, enclosure 600 with at least housing 610 and window 620 is configured to substantially attenuate radio-frequency (RF) electromagnetic radiation. For example, RF electromagnetic radiation emitted by lidar system 100 is attenuated by enclosure 600. Similarly, RF electromagnetic radiation emitted outside of lidar system 100 is also attenuated by enclosure 600. For example, RF electromagnetic radiation emitted from sources external to lidar system 100 that may otherwise interfere with the internal components of lidar system 100 is also attenuated by enclosure 600. The ability of enclosure 600 to attenuate RF electromagnetic radiation significantly improves the performance of lidar system 100. In various embodiments, the attenuation of the RF radiation of a frequency included in a range from 300 MHz to 6 GHz is greater than or equal to 5 dB.

In some embodiments, the diagram of lidar system 100 of FIG. 8 corresponds to the diagram of lidar system 100 of FIG. 3. For example, light source 110 emits output beam 125, which exits window 620 and is directed at an external target. Output beam 125 can be directed and/or aimed using scan mirror 302 and polygon mirror 301 at the external target. Input beam 135 is a received optical signal comprising at least a portion of emitted output beam 125 that is scattered by the external target. Input beam 135 passes through window 620 and via at least polygon mirror 301 and scan mirror 302 is received by receiver 140. Although not shown in FIG. 8, lidar system 100 can include additional mirrors such as mirror 115 of FIG. 3.

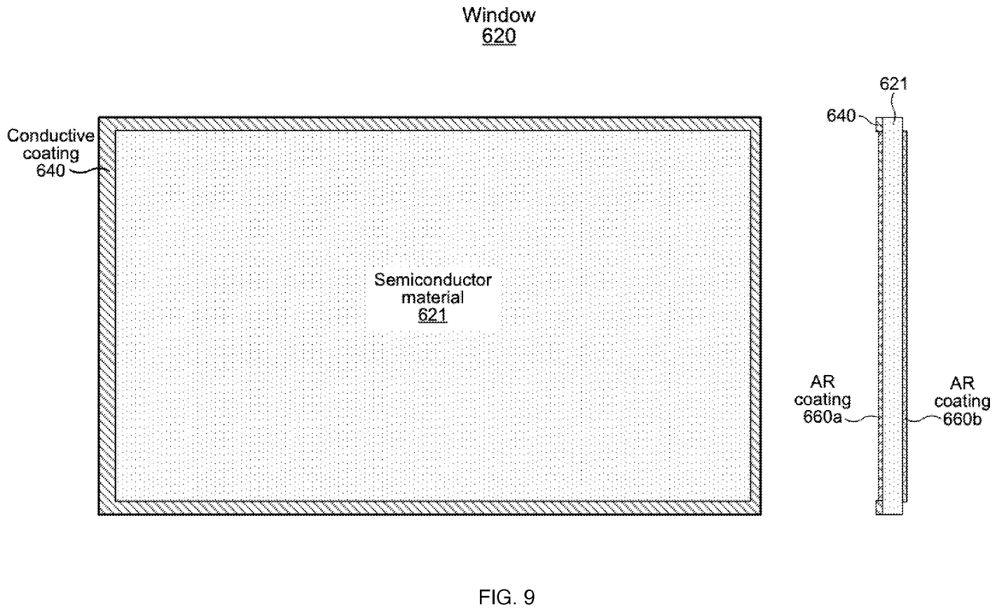

FIG. 9 illustrates an example window that includes a conductive coating. In the example shown, window 620 is a semiconductor window that includes semiconductor material 621, electrically conductive coating 640, and anti-reflection (AR) coatings 660a and 660b. For example, window 620 is a semiconductor window made of a semiconductor material such as semiconductor material 621. Window 620 is shown both with a head-on view looking through window 620 (center diagram) and from the side (right diagram). Window 620 can function as a window for a lidar system that allows optical signals of certain wavelengths to pass through while also attenuating electromagnetic radiation. In some embodiments, window 620 is window 620 of FIG. 8 of lidar system 100 of FIG. 8.

In various embodiments, window 620 is part of an enclosure (not shown) and includes conductive coating 640 that is used to bond window 620 including semiconductor material 621 to a housing (not shown) of the enclosure. In some embodiments, the housing associated with window 620 is housing 610 of FIG. 8 and the enclosure is enclosure 600 of FIG. 8. For example, conductive coating 640 can be deposited at or near an outer edge of window 620 and semiconductor material 621. Conductive coating 640 is electrically conductive and provides ohmic contact to semiconductor material 621 allowing semiconductor material 621 to be electrically coupled to the associated housing via conductive coating 640.

Examples of semiconductor material 621 include silicon or other semiconductor material. In an example, semiconductor material 621 is a crystalline silicon including either monocrystalline or polycrystalline silicon. In some embodiments, the semiconductor material 621 is a polysilicon material. In another example, the semiconductor material is an amorphous silicon material. In various embodiments, semiconductor material 621 of window 620 is doped with a p-type or n-type dopant configured to cause semiconductor material 621 to have a higher electrical conductivity than an undoped form of semiconductor material 621. For example, semiconductor material 621 is silicon doped with a p-type or n-type dopant having a dopant density of greater than or equal to 10¹⁴ atoms/cm³ and less than or equal to 10¹⁸ atoms/cm³. In some embodiments, semiconductor material 621 has an electrical conductivity of greater than or equal to 10 siemens per meter (S/m) and/or an electrical resistivity of less than or equal to 0.1 Ohm*m.

As shown in FIG. 9, window 620 can include anti-reflection (AR) coatings 660a and 660b deposited onto the surface of semiconductor material 621. AR coatings 660a and 660b are configured to reduce reflectivity of the surface of semiconductor material 621. In some embodiments, AR coatings 660a and 660b are selected to reduce reflectivity at one or more operating wavelengths of the system. For example, a lidar system can have one or more operating wavelengths between 900 nm and 2100 nm, and AR coatings 660a and 660b are selected to reduce reflectivity at the one or more operating wavelengths. In various embodiments, the operating wavelength can be one or more discrete wavelengths and/or one or more wavelength ranges. In various embodiments, AR coatings 660a and 660b are selected based on the refractive index of semiconductor material 621. Although two AR coatings 660a and 660b are shown for window 620, in some embodiments, only a single AR coating is utilized, for example, on an interior surface of window 620 and semiconductor material 621.

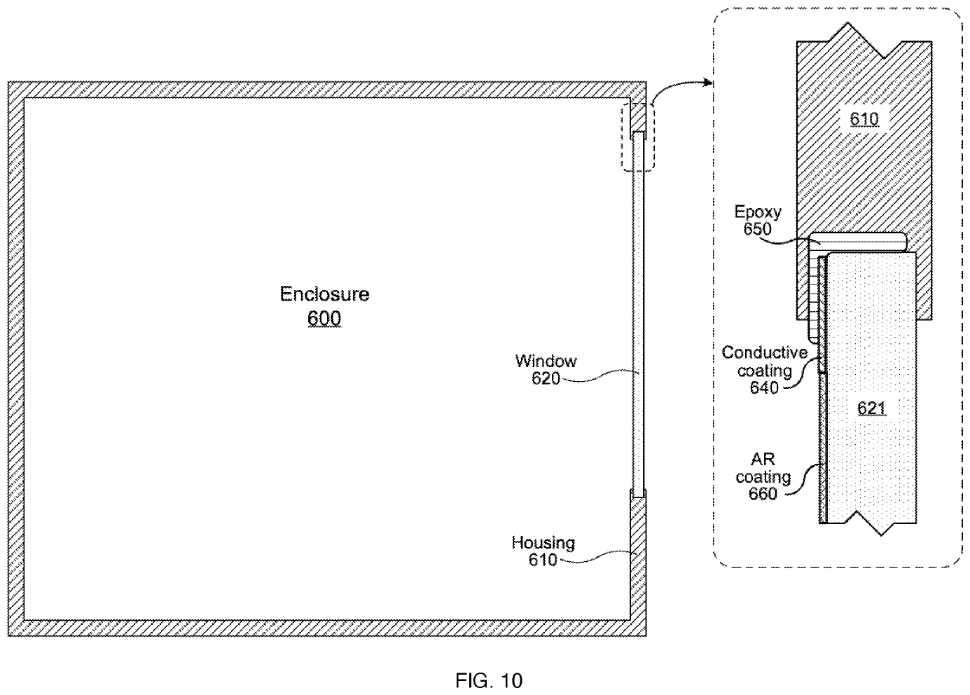

FIG. 10 illustrates an example enclosure that includes a housing, a window, and epoxy. In the example shown, enclosure 600 includes at least housing 610 and window 620. Window 620 is a semiconductor window made with a semiconductor material that covers an opening in housing 610. In the detailed view shown on the right of FIG. 10, window 620 includes semiconductor material 621, conductive coating 640, and anti-reflection (AR) coating 660. Window 620 is affixed to housing 610 using conductive epoxy 650. In various embodiments, window 620 corresponds to window 620 of FIG. 9 but with only a single AR coating on the interior surface of semiconductor material 621. In some embodiments, enclosure 600 is enclosure 600 of FIG. 8.

In various embodiments, conductive epoxy 650 is an electrically conductive epoxy or adhesive used to affix window 620 to housing 610. In various embodiments, conductive epoxy 650 provides at least an electrical coupling between window 620 and housing 610. In various embodiments, conductive epoxy 650 is electrically connected to housing 610, semiconductor material 621, and conductive coating 640. Although conductive epoxy 650 is shown labeled as an epoxy, another conductive adhesive that is not an epoxy can be utilized as an alternative.

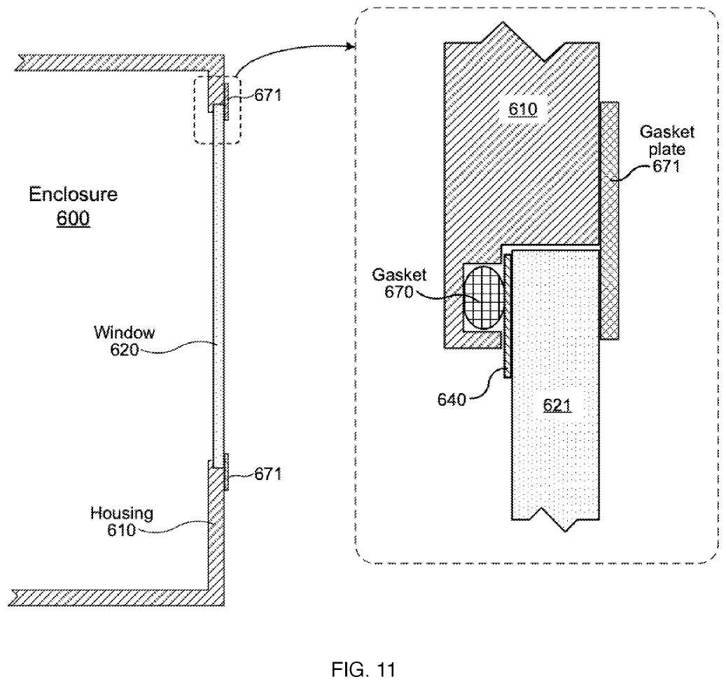

FIG. 11 illustrates an example enclosure that includes a housing, a window, and a gasket. In the example shown, enclosure 600 includes at least housing 610 and window 620. Window 620 is a semiconductor window made with a semiconductor material that covers an opening in housing 610. In the detailed view shown on the right of FIG. 11, window 620 includes semiconductor material 621 and conductive coating 640. In various embodiments, window 620 can include one or more anti-reflection (AR) coatings (not shown). Window 620 is affixed to housing 610 using conductive gasket 670 and gasket plate 671. In various embodiments, window 620 corresponds to window 620 of FIG. 9 but with AR coatings on semiconductor material 621. In some embodiments, enclosure 600 is enclosure 600 of FIG. 8.

In the example shown, conductive gasket 670 is an electrically conductive gasket disposed between the window 620 and housing 610 and is used at least in part to help seal window 620 to housing 610. In particular embodiments, conductive gasket 670 is configured to provide at least a portion or part of an electrical coupling between the housing 610, window 620, and semiconductor material 621. In some embodiments, conductive gasket 670 is an electromagnetic interference (EMI) gasket. As shown in FIG. 11, gasket plate 671 is utilized to fasten window 620 to housing 610. In some embodiments, gasket plate 671 is a metal plate attached to housing 610 using screws or another appropriate technique.

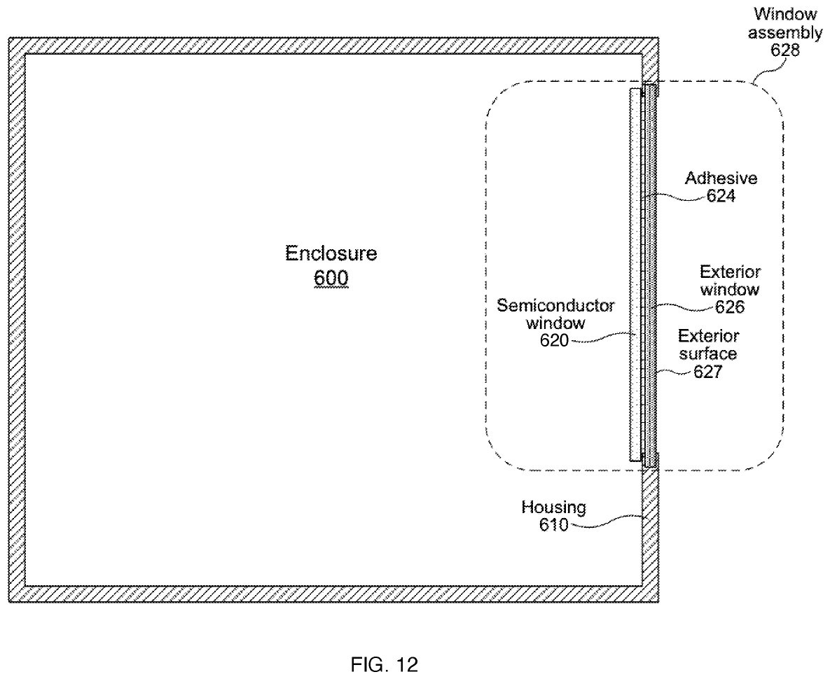

FIG. 12 illustrates an example window assembly that includes a semiconductor window and an exterior window. In the example shown, enclosure 600 includes at least housing 610 and window assembly 628. Window assembly 628 includes semiconductor window 620, adhesive 624, and exterior window 626. Exterior surface 627 is the exterior surface of exterior window 626 and faces the surrounding environment of enclosure 600. In some embodiments, exterior window 626 is located adjacent to semiconductor window 620 and provides an external-facing surface of a lidar system. In various embodiments, both semiconductor window 620 and exterior window 626 are optically transparent at the operating wavelengths of the lidar system. For example, in some embodiments, semiconductor window 620 is configured to allow at least a portion of emitted optical signals and received optical signals to pass through semiconductor window 620, and similarly, exterior window 626 is configured to allow at least a portion of emitted optical signals and received optical signals to pass through exterior window 626. For example, semiconductor window 620 can be configured to transmit greater than or equal to 90% of an optical signal emitted or received by a lidar system. In some embodiments, enclosure 600 is enclosure 600 of FIG. 8 and/or window assembly 628 is window 620 of FIG. 8.

As shown in FIG. 12, the embodiment of window assembly 628 includes two windows, semiconductor window 620 and exterior window 626. Semiconductor window 620 is protected from the external environment by exterior window 626. In various embodiments, exterior window 626 is affixed to housing 610 and semiconductor window 620 is affixed at least to exterior window 626 via adhesive 624. For example, portions of semiconductor window 620, such as and/or including portions around the edges and/or faces of semiconductor window 620, can be affixed to exterior window 626 using adhesive 624. In various embodiments, adhesive 624 is an optically clear adhesive. For example, adhesive 624, when applied between the faces of semiconductor window 620 and exterior window 626, allows optical signals of one or more wavelengths or wavelength ranges to exit and entering enclosure 600 via semiconductor window 620 and exterior window 626. In various embodiments, semiconductor window 620 and exterior window 626 are able to expand and contract based on conditions such as environmental conditions. For example, the coefficient of thermal expansion of semiconductor window 620 is approximately equal to a coefficient of thermal expansion of exterior window 626.

In some embodiments, semiconductor window 620 is paired with exterior window 626 but adhesive 624 is not necessary and semiconductor window 620 is affixed to housing 610 using the techniques of FIGS. 10 and/or 11 and/or other appropriate techniques that allow electrical conductivity between semiconductor window 620 and housing 610. For example, in some embodiments, semiconductor window 620 is window 620 of FIG. 10 and is affixed to housing 610 using a conductive epoxy or another conductive adhesive using at least the techniques disclosed with respect to FIG. 10. As another example, semiconductor window 620 can be affixed to housing 610 via a conductive gasket using at least the techniques disclosed with respect to FIG. 11. As yet another example, semiconductor window 620 can be affixed to housing 610 via capacitive coupling. For example, semiconductor window 620 can be electrically coupled to housing 610 by positioning semiconductor window 620 and housing 610 in the appropriate proximity from one another for capacitive coupling. In some embodiments, semiconductor window 620 and housing 610 can be electrically coupled via an electrically insulating layer system. In various embodiments, although semiconductor window 620 is paired with exterior window 626, an airgap or open space can exist between semiconductor window 620 and exterior window 626.

In some embodiments, exterior window 626 is designed to be a replaceable component of enclosure 600. For example, when degraded or broken, a faulty exterior window 626 can be replaced with a new exterior window 626. In some embodiments, exterior window 626 is affixed to housing 610 using bolts, screws, or another mechanism that allows exterior window 626 to be easily removed, replaced, and/or serviced. In some embodiments, exterior window 626 is attached in a more permanent manner that allows, impedes, or makes more difficult access to the components inside of enclosure 600. In particular embodiments, housing 610 is electrically conductive and includes an electrically conductive material, such as an electrically conductive metal.

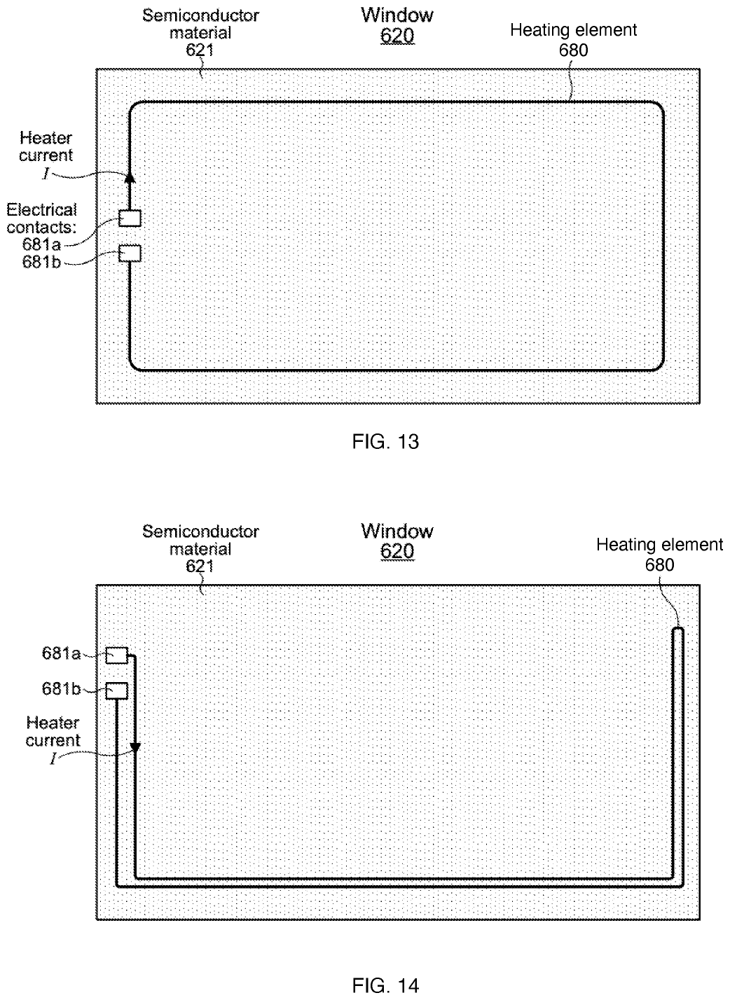

FIGS. 13-14 each illustrate an example window that includes a heating element. In the examples shown in FIGS. 13 and 14, window 620 is a semiconductor window that includes semiconductor material 621, heating element 680, and electrical contacts 681a and 681b. In various embodiments, window 620 of FIGS. 13 and/or 14 is window 620 of FIG. 8 of lidar system 100 of FIG. 8. In some embodiments, window 620 of FIGS. 13 and/or 14 is window 620 of FIGS. 9, 10, and/or 11 and/or semiconductor window 620 of FIG. 12. For example, window 620 of FIGS. 13 and/or 14 can include or be combined with additional components not shown including but not limited to conductive coatings, anti-reflection (AR) coatings, conductive adhesives, conductive gaskets, gasket plates, and/or a second exterior window using the techniques disclosed herein. In various embodiments, heating element 680 is connected to electrical contacts 681a and 681b and can carry heater current/to heat up and/or change the temperature of semiconductor material 621. In the example shown, heating element 680 is in thermal contact with semiconductor material 621 and is configured to receive an electrical current (shown as heater current I) and increase the temperature of the semiconductor material 621.

In various embodiments, FIGS. 13 and 14 display different layouts for heating element 680. In the examples shown, heating element 680 is positioned along at least portions of the perimeter of window 620 and semiconductor material 621. In FIG. 13, heating element 680 is positioned along all edges of semiconductor material 621. In FIG. 14, heating element 680 is positioned along only three of the four edges of semiconductor material 621. In various embodiments, electrical contacts 681a and 681b are both positioned near one another and/or on the same side or along the same edge of window 620 and semiconductor material 621. By positioning electrical contacts 681a and 681b near one another, their respective electrical connections (not shown) can be routed to one side of window 620 and/or can be routed together. In the examples shown, both electrical contacts 681a and 681b are positioned on the left edge of window 620 and semiconductor material 621.

In various embodiments, heating element 680 and/or electrical contacts 681a and 681b are electrically isolated from semiconductor material 621 and heating element 680 heats up semiconductor material 621, for example, via conduction. In some embodiments, heating element 680 is affixed to semiconductor material 621 by first depositing a layer of dielectric and then depositing heating element 680 on top of the deposited dielectric. For example, a dielectric layer is first deposited on top of which heating element 680 is deposited by screen printing or via another appropriate technique. In some embodiments, heating element 680 is implemented via a heating wire.

In various embodiments, when heater current I is applied to heating element 680, heating element 680 functions as a heater and semiconductor material 621 will increase in temperature. The heating functionality allows semiconductor material 621 to melt obstructions such as frozen water on or near the external-facing surface of the associated enclosure, such as an enclosure for a lidar system. For example, in the event window 620 is an exterior window or window 620 is paired with an exterior window, such as exterior window 626 of FIG. 12, heating element 680 can melt frozen water and/or other obstructions located on or near the external-facing surface associated with window 620, such as on an exterior window. For example, heating element 680 can melt ice, snow, frost, hail, sleet, or another frozen or semi-frozen obstruction on an associated external-facing surface. In some embodiments, window 620 is a semiconductor window that is part of a window assembly that includes a second window or window portion that is optically transparent at one or more operating wavelengths of a lidar system. The second window portion is an exterior window portion and is located adjacent to window 620 and provides an external-facing surface of the lidar system. By utilizing heating element 680, a temperature increase of window 620 is configured to increase the temperature of the second window. In some embodiments, an associated enclosure for window 620 is enclosure 600 of FIGS. 8, 10, 11, and/or 12.

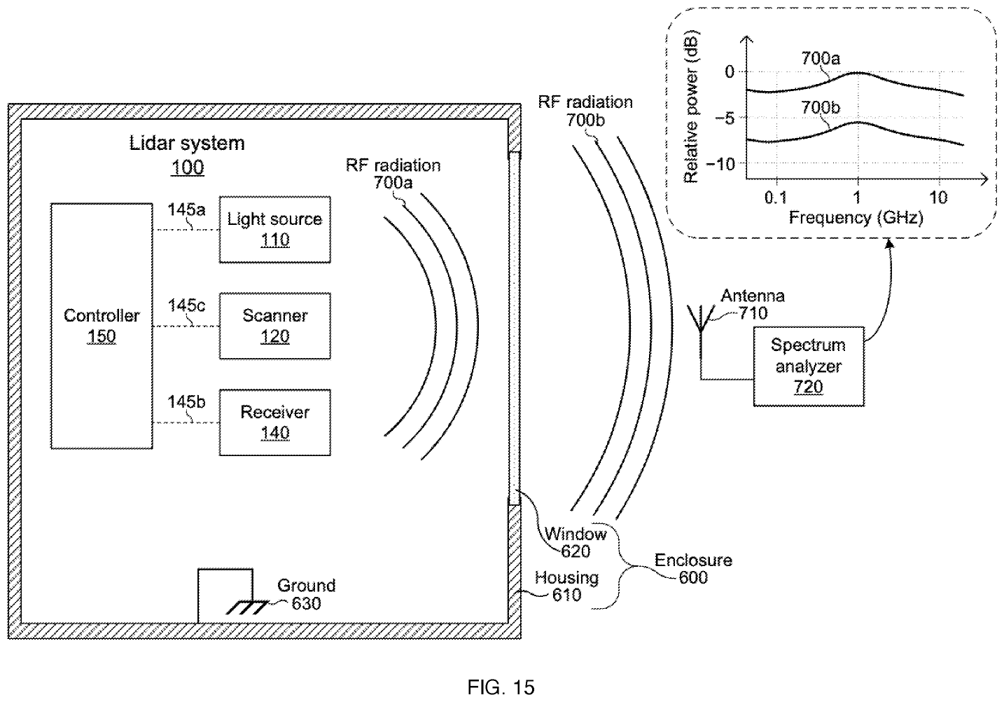

FIG. 15 illustrates an example measurement of radio-frequency (RF) electromagnetic radiation emitted by a lidar system. In the example shown, lidar system 100 includes enclosure 600 of lidar system 100. Enclosure 600 is attached to ground 630 and includes both housing 610 and window 620. As shown in FIG. 15, window 620 closes an opening in housing 610. In various embodiments, window 620 includes at least a semiconductor window made with a semiconductor material that reduces or suppresses electromagnetic interference (EMI) while maintaining optical transparency. Also shown in FIG. 15 is spectrum analyzer 720 with antenna 710 and radio-frequency (RF) radiation 700a and 700b. Two graphs of relative power v. frequency as would be measured by spectrum analyzer 720 are shown in the upper-right corner of FIG. 15 and include graphs with representative data for RF radiation 700a and RF radiation 700b. In some embodiments, window 620 is window 620 of FIGS. 8-11, 13, and/or 14 and/or includes at least semiconductor window 620 of FIG. 12. Lidar system 100 includes lidar components such as controller 150, light source 110, scanner 120, receiver 140, and enclosure 600 (among others not shown) and functions at least in part as described with respect to lidar system 100 of FIGS. 1-14.

In various embodiments, enclosure 600 with window 620 and housing 610 attenuates radio-frequency (RF) electromagnetic radiation using the techniques disclosed herein. For example, in various embodiments, window 620 is a semiconductor window electrically coupled to housing 610, which itself can be constructed using an electrically conductive material. Enclosure 600 is configured to substantially attenuate radio-frequency (RF) electromagnetic radiation emitted by lidar system 100. In various embodiments, RF radiation 700a and RF radiation 700b represent emitted radiation generated by lidar system 100, for example, RF radiation generated by electronic components within enclosure 600. RF radiation 700a represents the RF radiation within enclosure 600 and RF radiation 700b represents the RF radiation outside of enclosure 600 and after RF radiation corresponding to RF radiation 700a has been attenuated by at least window 620. The two representative graphs shown in FIG. 15 depict the representative relative power of the RF radiation when measured from within enclosure 600 and from outside of enclosure 600. Although the two representative graphs do not depict actual measured data, as shown in the representative graphs, the relative power of RF radiation 700a is higher than RF radiation 700b at least in part because housing 610 and window 620 attenuate RF electromagnetic radiation. In some embodiments, the attenuation of the RF radiation by enclosure 600 of a frequency included in a range from 300 MHz to 6 GHz is greater than or equal to 5 dB.

Although FIG. 15 depicts the relative attenuation of RF radiation generated by lidar system 100 by enclosure 600, enclosure 600 including housing 610 and window 620 also functions to attenuate RF radiation generated by sources external to lidar system 100. For example, RF radiation generated outside of lidar system 100 will have a relative power that is higher when measured outside of enclosure 600 than when measured inside of enclosure 600 due at least in part to window 620.

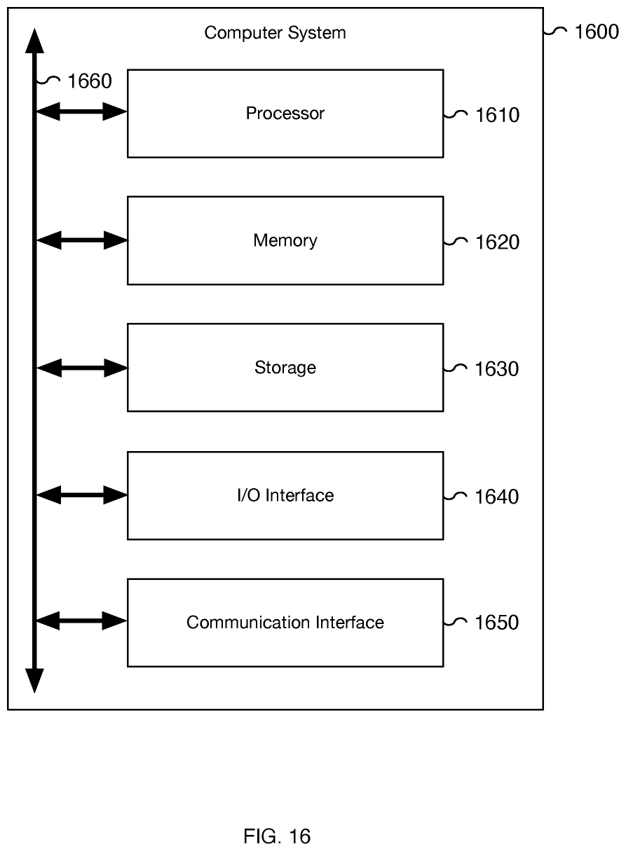

FIG. 16 illustrates an example computer system 1600. In particular embodiments, one or more computer systems 1600 may perform one or more steps of one or more methods described or illustrated herein. In particular embodiments, one or more computer systems 1600 may provide functionality described or illustrated herein. In particular embodiments, software running on one or more computer systems 1600 may perform one or more steps of one or more methods described or illustrated herein or may provide functionality described or illustrated herein. Particular embodiments may include one or more portions of one or more computer systems 1600. In particular embodiments, a computer system may be referred to as a processor, a controller, a computing device, a computing system, a computer, a general-purpose computer, or a data-processing apparatus. Herein, reference to a computer system may encompass one or more computer systems, where appropriate. In some embodiments, computer system 1600 is used to perform one or more of the processes associated with a lidar system that includes an enclosure with at least a semiconductor window that attenuates electromagnetic radiation. For example, computer system 1600 can be used at least in part to determine a distance from a lidar system to an external target based on a round-trip time for the portion of an emitted optical signal to travel from the lidar system, exiting through the disclosed semiconductor window, to the external target and back to the system, entering through the disclosed semiconductor window.

Computer system 1600 may take any suitable physical form. As an example, computer system 1600 may be an embedded computer system, a system-on-chip (SOC), a single-board computer system (SBC), a desktop computer system, a laptop or notebook computer system, a mainframe, a mesh of computer systems, a server, a tablet computer system, or any suitable combination of two or more of these. As another example, all or part of computer system 1600 may be combined with, coupled to, or integrated into a variety of devices, including, but not limited to, a camera, camcorder, personal digital assistant (PDA), mobile telephone, smartphone, electronic reading device (e.g., an e-reader), game console, smart watch, clock, calculator, television monitor, flat-panel display, computer monitor, vehicle display (e.g., odometer display or dashboard display), vehicle navigation system, lidar system, ADAS, autonomous vehicle, autonomous-vehicle driving system, cockpit control, camera view display (e.g., display of a rear-view camera in a vehicle), eyewear, or head-mounted display. Where appropriate, computer system 1600 may include one or more computer systems 1600; be unitary or distributed; span multiple locations; span multiple machines; span multiple data centers; or reside in a cloud, which may include one or more cloud components in one or more networks. Where appropriate, one or more computer systems 1600 may perform without substantial spatial or temporal limitation one or more steps of one or more methods described or illustrated herein. As an example, one or more computer systems 1600 may perform in real time or in batch mode one or more steps of one or more methods described or illustrated herein. One or more computer systems 1600 may perform at different times or at different locations one or more steps of one or more methods described or illustrated herein, where appropriate.

As illustrated in the example of FIG. 16, computer system 1600 may include a processor 1610, memory 1620, storage 1630, an input/output (I/O) interface 1640, a communication interface 1650, or a bus 1660. Computer system 1600 may include any suitable number of any suitable components in any suitable arrangement.

In particular embodiments, processor 1610 may include hardware for executing instructions, such as those making up a computer program. As an example, to execute instructions, processor 1610 may retrieve (or fetch) the instructions from an internal register, an internal cache, memory 1620, or storage 1630; decode and execute them; and then write one or more results to an internal register, an internal cache, memory 1620, or storage 1630. In particular embodiments, processor 1610 may include one or more internal caches for data, instructions, or addresses. Processor 1610 may include any suitable number of any suitable internal caches, where appropriate. As an example, processor 1610 may include one or more instruction caches, one or more data caches, or one or more translation lookaside buffers (TLBs). Instructions in the instruction caches may be copies of instructions in memory 1620 or storage 1630, and the instruction caches may speed up retrieval of those instructions by processor 1610. Data in the data caches may be copies of data in memory 1620 or storage 1630 for instructions executing at processor 1610 to operate on; the results of previous instructions executed at processor 1610 for access by subsequent instructions executing at processor 1610 or for writing to memory 1620 or storage 1630; or other suitable data. The data caches may speed up read or write operations by processor 1610. The TLBs may speed up virtual-address translation for processor 1610. In particular embodiments, processor 1610 may include one or more internal registers for data, instructions, or addresses. Processor 1610 may include any suitable number of any suitable internal registers, where appropriate. Where appropriate, processor 1610 may include one or more arithmetic logic units (ALUs); may be a multi-core processor; or may include one or more processors 1610.

In particular embodiments, memory 1620 may include main memory for storing instructions for processor 1610 to execute or data for processor 1610 to operate on. As an example, computer system 1600 may load instructions from storage 1630 or another source (such as, for example, another computer system 1600) to memory 1620. Processor 1610 may then load the instructions from memory 1620 to an internal register or internal cache. To execute the instructions, processor 1610 may retrieve the instructions from the internal register or internal cache and decode them. During or after execution of the instructions, processor 1610 may write one or more results (which may be intermediate or final results) to the internal register or internal cache. Processor 1610 may then write one or more of those results to memory 1620. One or more memory buses (which may each include an address bus and a data bus) may couple processor 1610 to memory 1620. Bus 1660 may include one or more memory buses. In particular embodiments, one or more memory management units (MMUs) may reside between processor 1610 and memory 1620 and facilitate accesses to memory 1620 requested by processor 1610. In particular embodiments, memory 1620 may include random access memory (RAM). This RAM may be volatile memory, where appropriate. Where appropriate, this RAM may be dynamic RAM (DRAM) or static RAM (SRAM). Memory 1620 may include one or more memories 1620, where appropriate.

In particular embodiments, storage 1630 may include mass storage for data or instructions. As an example, storage 1630 may include a hard disk drive (HDD), a floppy disk drive, flash memory, an optical disc, a magneto-optical disc, magnetic tape, or a Universal Serial Bus (USB) drive or a combination of two or more of these. Storage 1630 may include removable or non-removable (or fixed) media, where appropriate. Storage 1630 may be internal or external to computer system 1600, where appropriate. In particular embodiments, storage 1630 may be non-volatile, solid-state memory. In particular embodiments, storage 1630 may include read-only memory (ROM). Where appropriate, this ROM may be mask ROM (MROM), programmable ROM (PROM), erasable PROM (EPROM), electrically erasable PROM (EEPROM), flash memory, or a combination of two or more of these. Storage 1630 may include one or more storage control units facilitating communication between processor 1610 and storage 1630, where appropriate. Where appropriate, storage 1630 may include one or more storages 1630.

In particular embodiments, I/O interface 1640 may include hardware, software, or both, providing one or more interfaces for communication between computer system 1600 and one or more I/O devices. Computer system 1600 may include one or more of these I/O devices, where appropriate. One or more of these I/O devices may enable communication between a person and computer system 1600. As an example, an I/O device may include a keyboard, keypad, microphone, monitor, mouse, printer, scanner, speaker, camera, stylus, tablet, touch screen, trackball, another suitable I/O device, or any suitable combination of two or more of these. An I/O device may include one or more sensors. Where appropriate, I/O interface 1640 may include one or more device or software drivers enabling processor 1610 to drive one or more of these I/O devices. I/O interface 1640 may include one or more I/O interfaces 1640, where appropriate.

In particular embodiments, communication interface 1650 may include hardware, software, or both providing one or more interfaces for communication (such as, for example, packet-based communication) between computer system 1600 and one or more other computer systems 1600 or one or more networks. As an example, communication interface 1650 may include a network interface controller (NIC) or network adapter for communicating with an Ethernet or other wire-based network or a wireless NIC (WNIC); a wireless adapter for communicating with a wireless network, such as a WI-FI network; or an optical transmitter (e.g., a laser or a light-emitting diode) or an optical receiver (e.g., a photodetector) for communicating using fiber-optic communication or free-space optical communication. Computer system 1600 may communicate with an ad hoc network, a personal area network (PAN), an in-vehicle network (IVN), a local area network (LAN), a wide area network (WAN), a metropolitan area network (MAN), or one or more portions of the Internet or a combination of two or more of these. One or more portions of one or more of these networks may be wired or wireless. As an example, computer system 1600 may communicate with a wireless PAN (WPAN) (such as, for example, a BLUETOOTH WPAN), a WI-FI network, a Worldwide Interoperability for Microwave Access (WiMAX) network, a cellular telephone network (such as, for example, a Global System for Mobile Communications (GSM) network), or other suitable wireless network or a combination of two or more of these. As another example, computer system 1600 may communicate using fiber-optic communication based on 100 Gigabit Ethernet (100 GbE), 10 Gigabit Ethernet (10 GbE), or Synchronous Optical Networking (SONET). Computer system 1600 may include any suitable communication interface 1650 for any of these networks, where appropriate. Communication interface 1650 may include one or more communication interfaces 1650, where appropriate.

In particular embodiments, bus 1660 may include hardware, software, or both coupling components of computer system 1600 to each other. As an example, bus 1660 may include an Accelerated Graphics Port (AGP) or other graphics bus, a controller area network (CAN) bus, an Enhanced Industry Standard Architecture (EISA) bus, a front-side bus (FSB), a HYPERTRANSPORT (HT) interconnect, an Industry Standard Architecture (ISA) bus, an INFINIBAND interconnect, a low-pin-count (LPC) bus, a memory bus, a Micro Channel Architecture (MCA) bus, a Peripheral Component Interconnect (PCI) bus, a PCI-Express (PCIe) bus, a serial advanced technology attachment (SATA) bus, a Video Electronics Standards Association local bus (VLB), or another suitable bus or a combination of two or more of these. Bus 1660 may include one or more buses 1660, where appropriate.

In particular embodiments, various modules, circuits, systems, methods, or algorithm steps described in connection with the implementations disclosed herein may be implemented as electronic hardware, computer software, or any suitable combination of hardware and software. In particular embodiments, computer software (which may be referred to as software, computer-executable code, computer code, a computer program, computer instructions, or instructions) may be used to perform various functions described or illustrated herein, and computer software may be configured to be executed by or to control the operation of computer system 1600. As an example, computer software may include instructions configured to be executed by processor 1610. In particular embodiments, owing to the interchangeability of hardware and software, the various illustrative logical blocks, modules, circuits, or algorithm steps have been described generally in terms of functionality. Whether such functionality is implemented in hardware, software, or a combination of hardware and software may depend upon the particular application or design constraints imposed on the overall system.

In particular embodiments, a computing device may be used to implement various modules, circuits, systems, methods, or algorithm steps disclosed herein. As an example, all or part of a module, circuit, system, method, or algorithm disclosed herein may be implemented or performed by a general-purpose single- or multi-chip processor, a digital signal processor (DSP), an ASIC, a FPGA, any other suitable programmable-logic device, discrete gate or transistor logic, discrete hardware components, or any suitable combination thereof. A general-purpose processor may be a microprocessor, or, any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

In particular embodiments, one or more implementations of the subject matter described herein may be implemented as one or more computer programs (e.g., one or more modules of computer-program instructions encoded or stored on a computer-readable non-transitory storage medium). As an example, the steps of a method or algorithm disclosed herein may be implemented in a processor-executable software module which may reside on a computer-readable non-transitory storage medium. In particular embodiments, a computer-readable non-transitory storage medium may include any suitable storage medium that may be used to store or transfer computer software and that may be accessed by a computer system. Herein, a computer-readable non-transitory storage medium or media may include one or more semiconductor-based or other integrated circuits (ICs) (such, as for example, field-programmable gate arrays (FPGAs) or application-specific ICs (ASICs)), hard disk drives (HDDs), hybrid hard drives (HHDs), optical discs (e.g., compact discs (CDs), CD-ROM, digital versatile discs (DVDs), blu-ray discs, or laser discs), optical disc drives (ODDs), magneto-optical discs, magneto-optical drives, floppy diskettes, floppy disk drives (FDDs), magnetic tapes, flash memories, solid-state drives (SSDs), RAM, RAM-drives, ROM, SECURE DIGITAL cards or drives, any other suitable computer-readable non-transitory storage media, or any suitable combination of two or more of these, where appropriate. A computer-readable non-transitory storage medium may be volatile, non-volatile, or a combination of volatile and non-volatile, where appropriate.

In particular embodiments, certain features described herein in the context of separate implementations may also be combined and implemented in a single implementation. Conversely, various features that are described in the context of a single implementation may also be implemented in multiple implementations separately or in any suitable sub-combination. Moreover, although features may be described above as acting in certain combinations and even initially claimed as such, one or more features from a claimed combination may in some cases be excised from the combination, and the claimed combination may be directed to a sub-combination or variations of a sub-combination.

While operations may be depicted in the drawings as occurring in a particular order, this should not be understood as requiring that such operations be performed in the particular order shown or in sequential order, or that all operations be performed. Further, the drawings may schematically depict one more example processes or methods in the form of a flow diagram or a sequence diagram. However, other operations that are not depicted may be incorporated in the example processes or methods that are schematically illustrated. For example, one or more additional operations may be performed before, after, simultaneously with, or between any of the illustrated operations. Moreover, one or more operations depicted in a diagram may be repeated, where appropriate. Additionally, operations depicted in a diagram may be performed in any suitable order. Furthermore, although particular components, devices, or systems are described herein as carrying out particular operations, any suitable combination of any suitable components, devices, or systems may be used to carry out any suitable operation or combination of operations. In certain circumstances, multitasking or parallel processing operations may be performed. Moreover, the separation of various system components in the implementations described herein should not be understood as requiring such separation in all implementations, and it should be understood that the described program components and systems may be integrated together in a single software product or packaged into multiple software products.

Various embodiments have been described in connection with the accompanying drawings. However, it should be understood that the figures may not necessarily be drawn to scale. As an example, distances or angles depicted in the figures are illustrative and may not necessarily bear an exact relationship to actual dimensions or layouts of the devices illustrated.

The scope of this disclosure encompasses all changes, substitutions, variations, alterations, and modifications to the example embodiments described or illustrated herein that a person having ordinary skill in the art would comprehend. The scope of this disclosure is not limited to the example embodiments described or illustrated herein. Moreover, although this disclosure describes or illustrates respective embodiments herein as including particular components, elements, functions, operations, or steps, any of these embodiments may include any combination or permutation of any of the components, elements, functions, operations, or steps described or illustrated anywhere herein that a person having ordinary skill in the art would comprehend.

The term “or” as used herein is to be interpreted as an inclusive or meaning any one or any combination, unless expressly indicated otherwise or indicated otherwise by context. Therefore, herein, the expression “A or B” means “A, B, or both A and B.” As another example, herein, “A, B or C” means at least one of the following: A; B; C; A and B; A and C; B and C; A, B and C. An exception to this definition will occur if a combination of elements, devices, steps, or operations is in some way inherently mutually exclusive.

As used herein, words of approximation such as, without limitation, “approximately, “substantially,” or “about” refer to a condition that when so modified is understood to not necessarily be absolute or perfect but would be considered close enough to those of ordinary skill in the art to warrant designating the condition as being present. The extent to which the description may vary will depend on how great a change can be instituted and still have one of ordinary skill in the art recognize the modified feature as having the required characteristics or capabilities of the unmodified feature. In general, but subject to the preceding discussion, a numerical value herein that is modified by a word of approximation such as “approximately” may vary from the stated value by ±0.5%, ±1%, ±2%, ±3%, ±4%, ±5%, ±10%, ±12%, or ±15%. The term “substantially constant” refers to a value that varies by less than a particular amount over any suitable time interval. For example, a value that is substantially constant may vary by less than or equal to 20%, 10%, 1%, 0.5%, or 0.1% over a time interval of approximately 10⁴ s, 10³ s, 10² s, 10 s, 1 s, 100 ms, 10 ms, 1 ms, 100 μs, 10 μs, or 1 μs. The term “substantially constant” may be applied to any suitable value, such as for example, an optical power, a pulse repetition frequency, an electrical current, a wavelength, an optical or electrical frequency, or an optical or electrical phase.

As used herein, the terms “first,” “second,” “third,” etc. may be used as labels for nouns that they precede, and these terms may not necessarily imply a particular ordering (e.g., a particular spatial, temporal, or logical ordering). As an example, a system may be described as determining a “first result” and a “second result,” and the terms “first” and “second” may not necessarily imply that the first result is determined before the second result.

As used herein, the terms “based on” and “based at least in part on” may be used to describe or present one or more factors that affect a determination, and these terms may not exclude additional factors that may affect a determination. A determination may be based solely on those factors which are presented or may be based at least in part on those factors. The phrase “determine A based on B” indicates that B is a factor that affects the determination of A. In some instances, other factors may also contribute to the determination of A. In other instances, A may be determined based solely on B.

Although the foregoing embodiments have been described in some detail for purposes of clarity of understanding, the invention is not limited to the details provided. There are many alternative ways of implementing the invention. The disclosed embodiments are illustrative and not restrictive.

What is claimed is:

1. A system comprising:
a light source configured to emit an optical signal;
a receiver configured to detect a received optical signal comprising at least a portion of the emitted optical signal scattered by an external target; and
an enclosure comprising a housing and a semiconductor window, wherein:
the light source and the receiver are included in the enclosure; and
the semiconductor window comprises a semiconductor material configured to allow at least a portion of the emitted optical signal and the received optical signal to pass through the semiconductor window; and
the enclosure, including the housing and the semiconductor window, is configured to attenuate radio-frequency (RF) electromagnetic radiation.

2. The system of claim 1, wherein the semiconductor material is doped with a p-type or n-type dopant configured to cause the semiconductor material to have a higher electrical conductivity than an undoped form of the semiconductor material.

3. The system of claim 1, wherein the semiconductor material comprises silicon.

4. The system of claim 3, wherein the silicon is doped with a p-type or n-type dopant having a dopant density of greater than or equal to 10¹⁴ atoms/cm³ and less than or equal to 10¹⁸ atoms/cm³.

5. The system of claim 1, wherein the semiconductor material has an electrical conductivity of greater than or equal to 10 siemens per meter (S/m).

6. The system of claim 1, further comprising an electrically conductive coating configured to electrically couple the semiconductor material to the housing.

7. The system of claim 1, further comprising an electrically conductive epoxy or adhesive configured to (i) affix the semiconductor window to the housing and (ii) provide at least a portion of an electrical coupling between the semiconductor window and the housing.

8. The system of claim 1, further comprising an electrically conductive gasket disposed between the semiconductor window and the housing, wherein the gasket is configured to provide at least a portion of the electrical coupling between the semiconductor window and the housing.

9. The system of claim 1, wherein the semiconductor window is electrically coupled to the housing via capacitive coupling.

10. The system of claim 1, wherein the semiconductor window is a first window portion that is part of a window assembly, the window assembly further comprising a second window portion configured to allow at least a portion of the emitted optical signal and the received optical signal to pass through the second window portion, wherein the second window portion provides an external-facing surface of the system.

11. The system of claim 10, wherein the first window portion and the second window portion are coupled to one another by an optically clear adhesive.

12. The system of claim 1, wherein the housing comprises an electrically conductive metal.

13. The system of claim 1, wherein the enclosure is configured to attenuate radio-frequency (RF) electromagnetic radiation emitted by the system, and the attenuation of the RF radiation of a frequency included in a range from 300 MHz to 6 GHz is greater than or equal to 5 dB.

14. The system of claim 1, wherein the semiconductor window is configured to transmit greater than or equal to 90% of the emitted optical signal.

15. The system of claim 1, further comprising an anti-reflection (AR) coating deposited onto a surface of the semiconductor material, wherein the AR coating is configured to reduce a reflectivity of the surface of the semiconductor material at an operating wavelength of the system.

16. The system of claim 1, further comprising a heating element in thermal contact with the semiconductor material, wherein the heating element is configured to receive an electrical current and increase a temperature of the semiconductor material.

17. The system of claim 16, wherein the semiconductor window is a first window portion that is part of a window assembly, the window assembly further comprising a second window portion that is optically transparent at an operating wavelength of the system, wherein:
the second window portion provides an external-facing surface of the system; and
the temperature increase of the semiconductor material is configured to increase a temperature of the second window portion.

18. The system of claim 1, wherein
the emitted optical signal comprises an emitted pulse of light;
the received optical signal comprises a received pulse of light comprising a portion of the emitted pulse of light scattered by the external target;
the system includes a detector configured to produce a pulse of photocurrent corresponding to the received pulse of light;
the pulse of photocurrent comprises a pulse of electrical current; and
the receiver further comprises a transimpedance amplifier configured to amplify the pulse of electrical current to produce a voltage pulse that corresponds to the pulse of electrical current.

19. The system of claim 1, wherein the light source comprises:
a seed laser diode configured to produce a seed optical signal; and
a semiconductor optical amplifier (SOA) configured to amplify the seed optical signal to produce the emitted optical signal.

20. The system of claim 1, wherein the light source comprises:
a seed laser diode configured to produce a seed optical signal;
a semiconductor optical amplifier (SOA) configured to amplify the seed optical signal to produce an amplified seed optical signal; and
a fiber-optic amplifier configured to further amplify the amplified seed optical signal to produce the emitted optical signal.

21. The system of claim 1, wherein the system is a pulsed lidar system, and wherein the emitted optical signal comprises pulses of light with optical characteristics comprising:
one or more wavelengths between 900 nanometers and 2100 nanometers;
a pulse energy between 0.01 μJ and 100 μJ;
a pulse repetition frequency between 80 kHz and 10 MHz; and
a pulse duration between 1 ns and 100 ns.

22. The system of claim 1, wherein the system is a frequency-modulated continuous-wave (FMCW) lidar system and wherein:
the emitted optical signal comprises a frequency-modulated (FM) output-light signal;
the light source is further configured to emit an FM local-oscillator optical signal that is coherent with the FM output-light signal; and
the receiver is further configured to coherently mix the received optical signal and the FM local-oscillator optical signal, and wherein a photocurrent signal produced by an avalanche photodiode corresponds to the coherent mixing of the received optical signal and the FM local-oscillator optical signal.

23. The system of claim 1, further comprising a processor configured to determine a distance from the system to the external target based on a round-trip time for the portion of the emitted optical signal to travel from the system to the external target and back to the system.

24. A system comprising:
a light source configured to emit an optical signal;
a receiver configured to detect a received optical signal comprising at least a portion of the emitted optical signal scattered by an external target; and
an enclosure comprising a housing and a window assembly, wherein:
the light source and the receiver are included in the enclosure; and
the window assembly comprises a first window portion and a second window portion, the first window portion and the second window portion configured to allow at least a portion of the emitted optical signal and the received optical signal to pass through, wherein the first window portion is a semiconductor window comprising a semiconductor material, the second window portion provides an external-facing surface of the system, and the enclosure, including the housing and the semiconductor window, is configured to attenuate radio-frequency (RF) electromagnetic radiation.

25. A system comprising:
a light source configured to emit an optical signal;
a scanner configured to scan the emitted optical signal across a field of regard of the system;
a receiver configured to detect a received optical signal comprising at least a portion of the emitted optical signal scattered by an external target; and
an enclosure comprising a housing and a semiconductor window, wherein:
the light source, the scanner, and the receiver are included in the enclosure;
the housing comprises an electrically conductive metal; and
the semiconductor window comprises a semiconductor material and an anti-reflection (AR) coating deposited onto a surface of the semiconductor material, wherein the semiconductor material is configured to:
attenuate radio-frequency (RF) electromagnetic radiation at a frequency included in a range between 300 MHz to 6 GHz by greater than or equal to 5 dB;
transmit greater than or equal to 90% of the emitted optical signal; and
transmit greater than or equal to 90% of the received optical signal,
and wherein the AR coating is configured to reduce a reflectivity of the surface of the semiconductor material at an operating wavelength of the system.
